(19) United States
(12) Patent Application Publication
(10) Pub. No.: US 2026/0189250 A1
(43) Pub. Date: Jul. 2, 2026

(54) METHODS AND SYSTEMS FOR INCREMENTAL FREEZING WITH MULTI-KERNEL POLAR CODES

(71) Applicant: InterDigital Patent Holdings, Inc., Wilmington, DE (US)

(72) Inventors: Ahmet Serdar Tan, London (GB); Anouar Yatribi, London (GB); Arman Shojaeifard, London (GB); Javier Lorca Hernando, Madrid (ES)

(73) Assignee: InterDigital Patent Holdings, Inc., Wilmington, DE (US)

(21) Appl. No.: 19/131,006

(22) PCT Filed: Dec. 15, 2023
(86) PCT No.: PCT/US23/84280

§ 371 Date: May 19, 2025

Related U.S. Application Data
(60) Provisional application No. 63/432,828, filed on Dec. 15, 2022.
(60) Provisional application No. 63/433,217, filed on Dec. 16, 2022.
(60) Provisional application No. 63/433,326, filed on Dec. 16, 2022.

(51) Int. Cl. H03M 13/13; H03M 13/00; H04L 1/00; H04L 1/1812; H04L 1/1867

(52) U.S. Cl. CPC H03M 13/13; H03M 13/6306; H04L 1/1819; H04L 1/0041; H04L 1/1867

(57) ABSTRACT

An encoding device may encode data bits using a polar code associated with a first polar code kernel structure. The encoding device may send an initial transmission to a receiver. The initial transmission may include the polar coded data bits. The encoding device may receive first feedback from the receiver that indicates that at least a first subset of the data bits were not successfully decoded by the receiver. The encoding device may encode at least the first subset of the data bits that were not successfully decoded by the receiver using a polar code associated with a second polar code kernel structure using relatively higher reliability bit channels of the second polar code kernel structure than a reliability associated with one or more bit channels that were used for encoding the first subset of the data bits using the first polar code kernel structure of the initial transmission.

### CROSS-REFERENCE TO RELATED APPLICATIONS

This application claims the benefit of U.S. Provisional Patent Application No. 63/432,828 filed on Dec. 15, 2022, U.S. Provisional Patent Application No. 63/433,326 filed on Dec. 16, 2022, and U.S. Provisional Patent Application No. 63/433,217 filed on Dec. 16, 2022, the entire contents of which are incorporated herein by reference.

### BACKGROUND

Hybrid Automatic Repeat Request (HARQ) may be a technique that tries to ensure that one or more (e.g. all) information bits are successfully received in case of transmission failures. HARQ may combine forward error correction (FEC) with repeated transmissions which may contain one or more (e.g., all) or part of the information bits to increase the probability of decoding success after the retransmissions. Control channels may not use retransmissions and/or enabling HARQ functionality with polar codes may be currently an active research field.

### SUMMARY

A method may be implemented by an encoding device. The encoding device may encode data bits using a polar code associated with a first polar code kernel structure. The encoding device may send an initial transmission to a receiver. The initial transmission may comprise the polar coded data bits. The encoding device may receive first feedback from the receiver for the initial transmission. The first feedback may indicate that at least a first subset of the data bits were not successfully decoded by the receiver. The encoding device may encode at least the first subset of the data bits that were not successfully decoded by the receiver using a polar code associated with a second polar code kernel structure. The first subset of the data bits may be encoded using relatively higher reliability bit channels of the second polar code kernel structure than a reliability associated with one or more bit channels that were used for encoding the first subset of the data bits using the first polar code kernel structure of the initial transmission. The encoding device may send a first retransmission to the receiver. The first retransmission may comprise the polar coded first subset of the data bits associated with the second polar code kernel structure.

The encoding device may receive second feedback from the receiver for the first retransmission. The second feedback may indicate that at least a second subset of data bits were not successfully decoded by the receiver. The second subset of the data bits may be a subset of the first subset of the data bits. The encoding device may encode at least the second subset of the data bits using a polar code associated with a third polar code kernel structure. The second subset of the data bits may be encoded using relatively higher reliability bit channels of the third polar code kernel structure than a reliability associated with one or more bit channels that were used for encoding the second subset of the data bits using the second polar code kernel structure of the first retransmission. The encoding device may send a second retransmission to the receiver. The second retransmission may comprise the polar coded second subset of the data bits.

The encoding device may send one or more indication(s) of the first or second polar code kernel structure for the first retransmission and/or an indication of a mapping of the first subset of the data bits to the bit channels of the second polar code kernel structure to the receiver.

The first feedback, indicating that at least the first subset of the data bits were not successfully decoded by the receiver, may comprise one or more NACK messages. A code rate may be determined for the initial transmission based on a modulation and coding scheme (MCS). The respective data bits may be mapped to the first set of bit channels in the initial transmission and the first retransmission based on the respective reliabilities of the data bits. The first polar code kernel structure may comprise a first kernel order, a first kernel size, and/or a first kernel structure. The second polar code kernel structure may comprise a second kernel order, a second kernel size, and/or a second kernel structure.

The encoding device may select the first polar code kernel structure based on channel quality, a size of resources, encoder complexity, or reliability. The encoding device may select the second polar code kernel structure based on a code rate. The code rate may be associated with the first transmission.

The encoding device may determine a code rate for the first retransmission based on a pre-defined set of code rates. The encoding device may determine a code rate for the first retransmission based on a signal to noise ratio associated with the initial transmission.

### BRIEF DESCRIPTION OF THE DRAWINGS

FIG. 1A is a system diagram illustrating an example communications system in which one or more disclosed embodiments may be implemented.

FIG. 1B is a system diagram illustrating an example wireless transmit/receive unit (WTRU) that may be used within the communications system illustrated in FIG. 1A according to an embodiment.

FIG. 1C is a system diagram illustrating an example radio access network (RAN) and an example core network (CN) that may be used within the communications system illustrated in FIG. 1A according to an embodiment.

FIG. 1D is a system diagram illustrating a further example RAN and a further example CN that may be used within the communications system illustrated in FIG. 1A according to an embodiment.

FIG. 2 is a diagram depicting an example polar encoder of block size 8.

FIG. 3 is a diagram depicting an example multi-kernel polar encoder with codeword size 12.

FIG. 4 is a diagram depicting another example multi-kernel polar encoder with codeword size 15.

FIG. 5 is a flow diagram depicting an example multi-kernel polar code framework.

FIG. 6 is a flowchart depicting an example multi-kernel encoding process at a transmitter (TX).

FIG. 7 is a flowchart depicting an example multi-kernel decoding processes at a receiver (RX).

FIG. 8 is a flow diagram depicting an example IF-HARQ enabled multi-kernel polar framework.

FIG. 9 is a flowchart depicting an example IF-HARQ process at the receiver (RX).

FIG. 10 is a flowchart depicting an example IF-HARQ process at the transmitter (TX).

### DETAILED DESCRIPTION

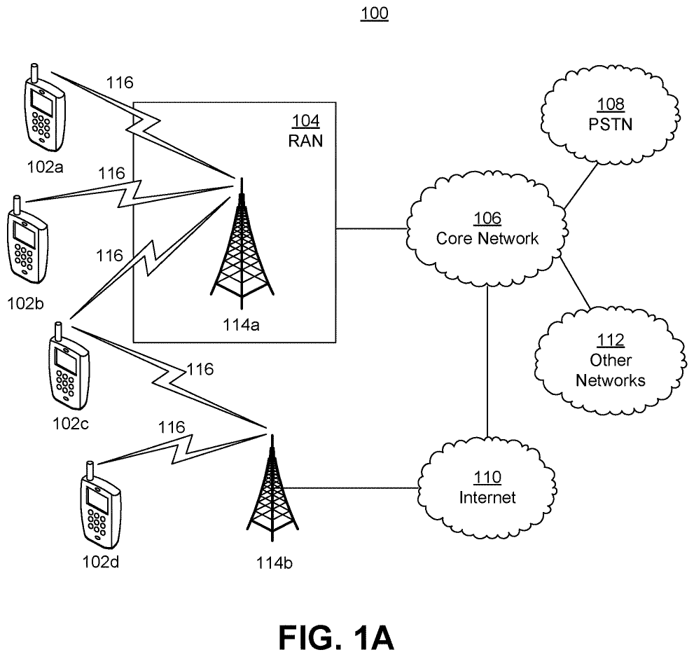

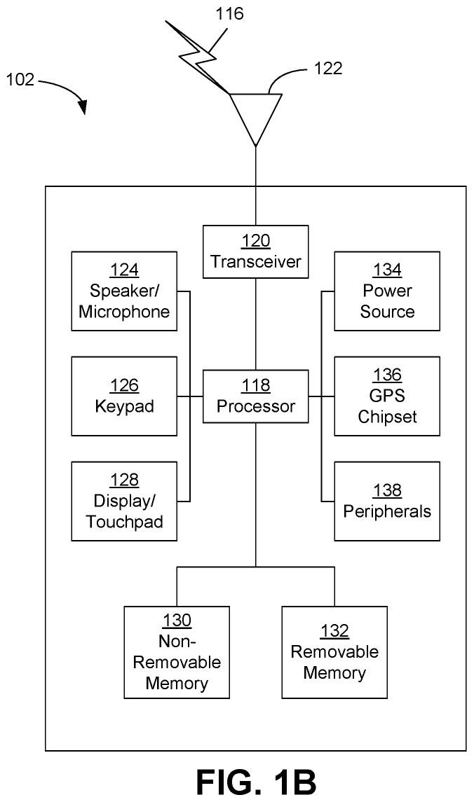

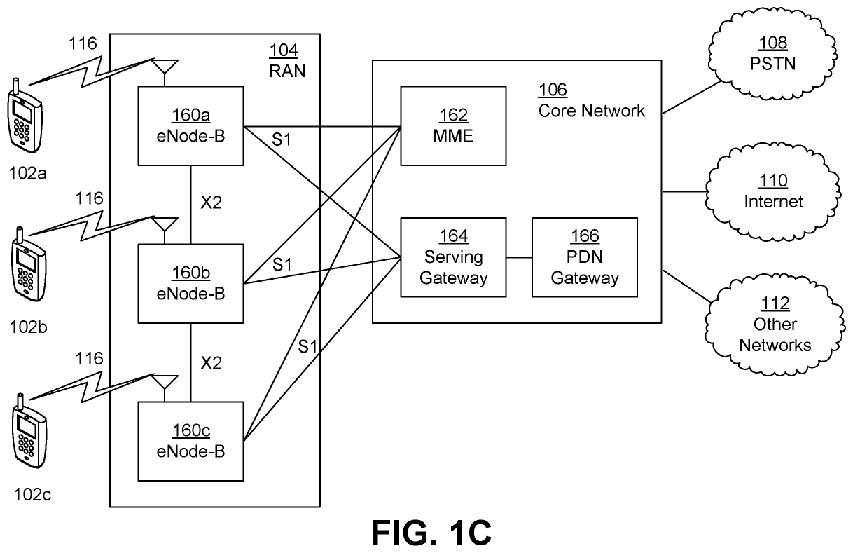

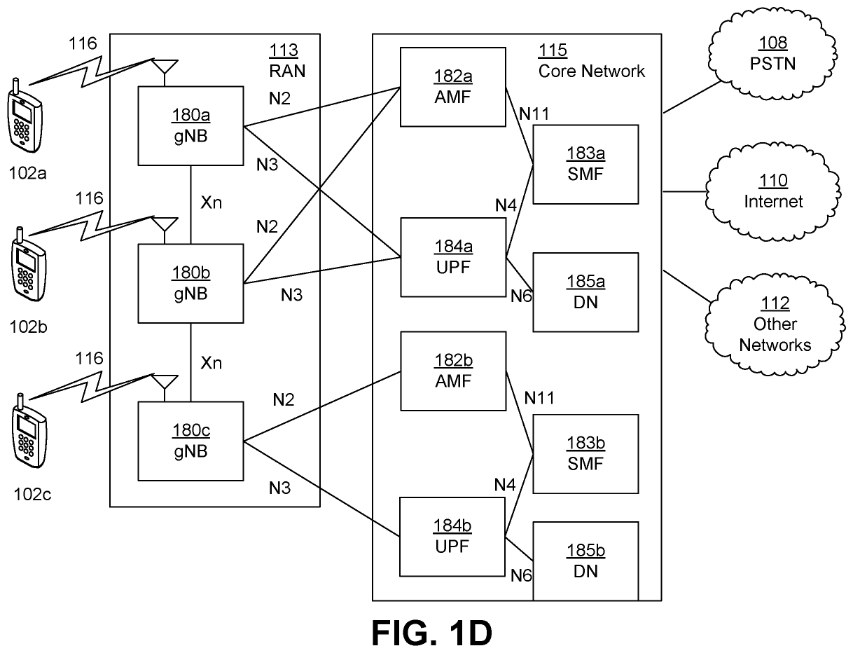

FIG. 1A is a diagram illustrating an example communications system 100 in which one or more disclosed embodiments may be implemented. The communications system 100 may be a multiple access system that provides content, such as voice, data, video, messaging, broadcast, etc., to multiple wireless users. The communications system 100 may enable multiple wireless users to access such content through the sharing of system resources, including wireless bandwidth. For example, the communications systems 100 may employ one or more channel access methods, such as code division multiple access (CDMA), time division multiple access (TDMA), frequency division multiple access (FDMA), orthogonal FDMA (OFDMA), single-carrier FDMA (SC-FDMA), zero-tail unique-word DFT-Spread OFDM (ZT UW DTS-s OFDM), unique word OFDM (UW-OFDM), resource block-filtered OFDM, filter bank multicarrier (FBMC), and the like.

As shown in FIG. 1A, the communications system 100 may include wireless transmit/receive units (WTRUs) 102a, 102b, 102c, 102d, a RAN 104/113, a CN 106/115, a public switched telephone network (PSTN) 108, the Internet 110, and other networks 112, though it will be appreciated that the disclosed embodiments contemplate any number of WTRUs, base stations, networks, and/or network elements. Each of the WTRUs 102a, 102b, 102c, 102d may be any type of device configured to operate and/or communicate in a wireless environment. By way of example, the WTRUs 102a, 102b, 102c, 102d, any of which may be referred to as a “station” and/or a “STA”, may be configured to transmit and/or receive wireless signals and may include a user equipment (UE), a mobile station, a fixed or mobile subscriber unit, a subscription-based unit, a pager, a cellular telephone, a personal digital assistant (PDA), a smartphone, a laptop, a netbook, a personal computer, a wireless sensor, a hotspot or Mi-Fi device, an Internet of Things (IoT) device, a watch or other wearable, a head-mounted display (HMD), a vehicle, a drone, a medical device and applications (e.g., remote surgery), an industrial device and applications (e.g., a robot and/or other wireless devices operating in an industrial and/or an automated processing chain contexts), a consumer electronics device, a device operating on commercial and/or industrial wireless networks, and the like. Any of the WTRUs 102a, 102b, 102c and 102d may be interchangeably referred to as a UE.

The communications systems 100 may also include a base station 114a and/or a base station 114b. Each of the base stations 114a, 114b may be any type of device configured to wirelessly interface with at least one of the WTRUs 102a, 102b, 102c, 102d to facilitate access to one or more communication networks, such as the CN 106/115, the Internet 110, and/or the other networks 112. By way of example, the base stations 114a, 114b may be a base transceiver station (BTS), a Node-B, an eNode B, a Home Node B, a Home eNode B, a gNB, a NR NodeB, a site controller, an access point (AP), a wireless router, and the like. While the base stations 114a, 114b are each depicted as a single element, it will be appreciated that the base stations 114a, 114b may include any number of interconnected base stations and/or network elements.

The base station 114a may be part of the RAN 104/113, which may also include other base stations and/or network elements (not shown), such as a base station controller (BSC), a radio network controller (RNC), relay nodes, etc. The base station 114a and/or the base station 114b may be configured to transmit and/or receive wireless signals on one or more carrier frequencies, which may be referred to as a cell (not shown). These frequencies may be in licensed spectrum, unlicensed spectrum, or a combination of licensed and unlicensed spectrum. A cell may provide coverage for a wireless service to a specific geographical area that may be relatively fixed or that may change over time. The cell may further be divided into cell sectors. For example, the cell associated with the base station 114a may be divided into three sectors. Thus, in one embodiment, the base station 114a may include three transceivers, i.e., one for each sector of the cell. In an embodiment, the base station 114a may employ multiple-input multiple output (MIMO) technology and may utilize multiple transceivers for each sector of the cell. For example, beamforming may be used to transmit and/or receive signals in desired spatial directions.

The base stations 114a, 114b may communicate with one or more of the WTRUs 102a, 102b, 102c, 102d over an air interface 116, which may be any suitable wireless communication link (e.g., radio frequency (RF), microwave, centimeter wave, micrometer wave, infrared (IR), ultraviolet (UV), visible light, etc.). The air interface 116 may be established using any suitable radio access technology (RAT).

More specifically, as noted above, the communications system 100 may be a multiple access system and may employ one or more channel access schemes, such as CDMA, TDMA, FDMA, OFDMA, SC-FDMA, and the like. For example, the base station 114a in the RAN 104/113 and the WTRUs 102a, 102b, 102c may implement a radio technology such as Universal Mobile Telecommunications System (UMTS) Terrestrial Radio Access (UTRA), which may establish the air interface 115/116/117 using wideband CDMA (WCDMA). WCDMA may include communication protocols such as High-Speed Packet Access (HSPA) and/or Evolved HSPA (HSPA+). HSPA may include High-Speed Downlink (DL) Packet Access (HSDPA) and/or High-Speed UL Packet Access (HSUPA).

In an embodiment, the base station 114a and the WTRUs 102a, 102b, 102c may implement a radio technology such as Evolved UMTS Terrestrial Radio Access (E-UTRA), which may establish the air interface 116 using Long Term Evolution (LTE) and/or LTE-Advanced (LTE-A) and/or LTE-Advanced Pro (LTE-A Pro).

In an embodiment, the base station 114a and the WTRUs 102a, 102b, 102c may implement a radio technology such as NR Radio Access, which may establish the air interface 116 using New Radio (NR).

In an embodiment, the base station 114a and the WTRUs 102a, 102b, 102c may implement multiple radio access technologies. For example, the base station 114a and the WTRUs 102a, 102b, 102c may implement LTE radio access and NR radio access together, for instance using dual connectivity (DC) principles. Thus, the air interface utilized by WTRUs 102a, 102b, 102c may be characterized by multiple types of radio access technologies and/or transmissions sent to/from multiple types of base stations (e.g., a eNB and a gNB).

In other embodiments, the base station 114a and the WTRUs 102a, 102b, 102c may implement radio technologies such as IEEE 802.11 (i.e., Wireless Fidelity (WiFi), IEEE 802.16 (i.e., Worldwide Interoperability for Microwave Access (WiMAX)), CDMA2000, CDMA2000 1×, CDMA2000 EV-DO, Interim Standard 2000 (IS-2000), Interim Standard 95 (IS-95), Interim Standard 856 (IS-856), Global System for Mobile communications (GSM), Enhanced Data rates for GSM Evolution (EDGE), GSM EDGE (GERAN), and the like.

The base station 114b in FIG. 1A may be a wireless router, Home Node B, Home eNode B, or access point, for example, and may utilize any suitable RAT for facilitating wireless connectivity in a localized area, such as a place of business, a home, a vehicle, a campus, an industrial facility, an air corridor (e.g., for use by drones), a roadway, and the like. In one embodiment, the base station 114b and the WTRUs 102c, 102d may implement a radio technology such as IEEE 802.11 to establish a wireless local area network (WLAN). In an embodiment, the base station 114b and the WTRUs 102c, 102d may implement a radio technology such as IEEE 802.15 to establish a wireless personal area network (WPAN). In yet another embodiment, the base station 114b and the WTRUs 102c, 102d may utilize a cellular-based RAT (e.g., WCDMA, CDMA2000, GSM, LTE, LTE-A, LTE-A Pro, NR etc.) to establish a picocell or femtocell. As shown in FIG. 1A, the base station 114b may have a direct connection to the Internet 110. Thus, the base station 114b may not be required to access the Internet 110 via the CN 106/115.

The RAN 104/113 may be in communication with the CN 106/115, which may be any type of network configured to provide voice, data, applications, and/or voice over internet protocol (VoIP) services to one or more of the WTRUs 102a, 102b, 102c, 102d. The data may have varying quality of service (QoS) requirements, such as differing throughput requirements, latency requirements, error tolerance requirements, reliability requirements, data throughput requirements, mobility requirements, and the like. The CN 106/115 may provide call control, billing services, mobile location-based services, pre-paid calling, Internet connectivity, video distribution, etc., and/or perform high-level security functions, such as user authentication. Although not shown in FIG. 1A, it will be appreciated that the RAN 104/113 and/or the CN 106/115 may be in direct or indirect communication with other RANs that employ the same RAT as the RAN 104/113 or a different RAT. For example, in addition to being connected to the RAN 104/113, which may be utilizing a NR radio technology, the CN 106/115 may also be in communication with another RAN (not shown) employing a GSM, UMTS, CDMA 2000, WIMAX, E-UTRA, or WiFi radio technology.

The CN 106/115 may also serve as a gateway for the WTRUs 102a, 102b, 102c, 102d to access the PSTN 108, the Internet 110, and/or the other networks 112. The PSTN 108 may include circuit-switched telephone networks that provide plain old telephone service (POTS). The Internet 110 may include a global system of interconnected computer networks and devices that use common communication protocols, such as the transmission control protocol (TCP), user datagram protocol (UDP) and/or the internet protocol (IP) in the TCP/IP internet protocol suite. The networks 112 may include wired and/or wireless communications networks owned and/or operated by other service providers. For example, the networks 112 may include another CN connected to one or more RANs, which may employ the same RAT as the RAN 104/113 or a different RAT.

Some or all of the WTRUs 102a, 102b, 102c, 102d in the communications system 100 may include multi-mode capabilities (e.g., the WTRUs 102a, 102b, 102c, 102d may include multiple transceivers for communicating with different wireless networks over different wireless links). For example, the WTRU 102c shown in FIG. 1A may be configured to communicate with the base station 114a, which may employ a cellular-based radio technology, and with the base station 114b, which may employ an IEEE 802 radio technology.

FIG. 1B is a system diagram illustrating an example WTRU 102. As shown in FIG. 1B, the WTRU 102 may include a processor 118, a transceiver 120, a transmit/receive element 122, a speaker/microphone 124, a keypad 126, a display/touchpad 128, non-removable memory 130, removable memory 132, a power source 134, a global positioning system (GPS) chipset 136, and/or other peripherals 138, among others. It will be appreciated that the WTRU 102 may include any sub-combination of the foregoing elements while remaining consistent with an embodiment.

The processor 118 may be a general purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), a state machine, and the like. The processor 118 may perform signal coding, data processing, power control, input/output processing, and/or any other functionality that enables the WTRU 102 to operate in a wireless environment. The processor 118 may be coupled to the transceiver 120, which may be coupled to the transmit/receive element 122. While FIG. 1B depicts the processor 118 and the transceiver 120 as separate components, it will be appreciated that the processor 118 and the transceiver 120 may be integrated together in an electronic package or chip.

The transmit/receive element 122 may be configured to transmit signals to, or receive signals from, a base station (e.g., the base station 114a) over the air interface 116. For example, in one embodiment, the transmit/receive element 122 may be an antenna configured to transmit and/or receive RF signals. In an embodiment, the transmit/receive element 122 may be an emitter/detector configured to transmit and/or receive IR, UV, or visible light signals, for example. In yet another embodiment, the transmit/receive element 122 may be configured to transmit and/or receive both RF and light signals. It will be appreciated that the transmit/receive element 122 may be configured to transmit and/or receive any combination of wireless signals.

Although the transmit/receive element 122 is depicted in FIG. 1B as a single element, the WTRU 102 may include any number of transmit/receive elements 122. More specifically, the WTRU 102 may employ MIMO technology. Thus, in one embodiment, the WTRU 102 may include two or more transmit/receive elements 122 (e.g., multiple antennas) for transmitting and receiving wireless signals over the air interface 116.

The transceiver 120 may be configured to modulate the signals that are to be transmitted by the transmit/receive element 122 and to demodulate the signals that are received by the transmit/receive element 122. As noted above, the WTRU 102 may have multi-mode capabilities. Thus, the transceiver 120 may include multiple transceivers for enabling the WTRU 102 to communicate via multiple RATs, such as NR and IEEE 802.11, for example.

The processor 118 of the WTRU 102 may be coupled to, and may receive user input data from, the speaker/microphone 124, the keypad 126, and/or the display/touchpad 128 (e.g., a liquid crystal display (LCD) display unit or organic light-emitting diode (OLED) display unit). The processor 118 may also output user data to the speaker/microphone 124, the keypad 126, and/or the display/touchpad 128. In addition, the processor 118 may access information from, and store data in, any type of suitable memory, such as the non-removable memory 130 and/or the removable memory 132. The non-removable memory 130 may include random-access memory (RAM), read-only memory (ROM), a hard disk, or any other type of memory storage device. The removable memory 132 may include a subscriber identity module (SIM) card, a memory stick, a secure digital (SD) memory card, and the like. In other embodiments, the processor 118 may access information from, and store data in, memory that is not physically located on the WTRU 102, such as on a server or a home computer (not shown).

The processor 118 may receive power from the power source 134, and may be configured to distribute and/or control the power to the other components in the WTRU 102. The power source 134 may be any suitable device for powering the WTRU 102. For example, the power source 134 may include one or more dry cell batteries (e.g., nickel-cadmium (NiCd), nickel-zinc (NiZn), nickel metal hydride (NiMH), lithium-ion (Li-ion), etc.), solar cells, fuel cells, and the like.

The processor 118 may also be coupled to the GPS chipset 136, which may be configured to provide location information (e.g., longitude and latitude) regarding the current location of the WTRU 102. In addition to, or in lieu of, the information from the GPS chipset 136, the WTRU 102 may receive location information over the air interface 116 from a base station (e.g., base stations 114a, 114b) and/or determine its location based on the timing of the signals being received from two or more nearby base stations. It will be appreciated that the WTRU 102 may acquire location information by way of any suitable location-determination method while remaining consistent with an embodiment.

The processor 118 may further be coupled to other peripherals 138, which may include one or more software and/or hardware modules that provide additional features, functionality and/or wired or wireless connectivity. For example, the peripherals 138 may include an accelerometer, an e-compass, a satellite transceiver, a digital camera (for photographs and/or video), a universal serial bus (USB) port, a vibration device, a television transceiver, a hands free headset, a Bluetooth® module, a frequency modulated (FM) radio unit, a digital music player, a media player, a video game player module, an Internet browser, a Virtual Reality and/or Augmented Reality (VR/AR) device, an activity tracker, and the like. The peripherals 138 may include one or more sensors, the sensors may be one or more of a gyroscope, an accelerometer, a hall effect sensor, a magnetometer, an orientation sensor, a proximity sensor, a temperature sensor, a time sensor; a geolocation sensor; an altimeter, a light sensor, a touch sensor, a magnetometer, a barometer, a gesture sensor, a biometric sensor, and/or a humidity sensor.

The WTRU 102 may include a full duplex radio for which transmission and reception of some or all of the signals (e.g., associated with particular subframes for both the UL (e.g., for transmission) and downlink (e.g., for reception) may be concurrent and/or simultaneous. The full duplex radio may include an interference management unit 139 to reduce and or substantially eliminate self-interference via either hardware (e.g., a choke) or signal processing via a processor (e.g., a separate processor (not shown) or via processor 118). In an embodiment, the WRTU 102 may include a half-duplex radio for which transmission and reception of some or all of the signals (e.g., associated with particular subframes for either the UL (e.g., for transmission) or the downlink (e.g., for reception)).

FIG. 1C is a system diagram illustrating the RAN 104 and the CN 106 according to an embodiment. As noted above, the RAN 104 may employ an E-UTRA radio technology to communicate with the WTRUs 102a, 102b, 102c over the air interface 116. The RAN 104 may also be in communication with the CN 106.

The RAN 104 may include eNode-Bs 160a, 160b, 160c, though it will be appreciated that the RAN 104 may include any number of eNode-Bs while remaining consistent with an embodiment. The eNode-Bs 160a, 160b, 160c may each include one or more transceivers for communicating with the WTRUs 102a, 102b, 102c over the air interface 116. In one embodiment, the eNode-Bs 160a, 160b, 160c may implement MIMO technology. Thus, the eNode-B 160a, for example, may use multiple antennas to transmit wireless signals to, and/or receive wireless signals from, the WTRU 102a.

Each of the eNode-Bs 160a, 160b, 160c may be associated with a particular cell (not shown) and may be configured to handle radio resource management decisions, handover decisions, scheduling of users in the UL and/or DL, and the like. As shown in FIG. 1C, the eNode-Bs 160a, 160b, 160c may communicate with one another over an X2 interface.

The CN 106 shown in FIG. 1C may include a mobility management entity (MME) 162, a serving gateway (SGW) 164, and a packet data network (PDN) gateway (or PGW) 166. While each of the foregoing elements are depicted as part of the CN 106, it will be appreciated that any of these elements may be owned and/or operated by an entity other than the CN operator.

The MME 162 may be connected to each of the eNode-Bs 162a, 162b, 162c in the RAN 104 via an S1 interface and may serve as a control node. For example, the MME 162 may be responsible for authenticating users of the WTRUs 102a, 102b, 102c, bearer activation/deactivation, selecting a particular serving gateway during an initial attach of the WTRUs 102a, 102b, 102c, and the like. The MME 162 may provide a control plane function for switching between the RAN 104 and other RANs (not shown) that employ other radio technologies, such as GSM and/or WCDMA.

The SGW 164 may be connected to each of the eNode Bs 160a, 160b, 160c in the RAN 104 via the S1 interface. The SGW 164 may generally route and forward user data packets to/from the WTRUs 102a, 102b, 102c. The SGW 164 may perform other functions, such as anchoring user planes during inter-eNode B handovers, triggering paging when DL data is available for the WTRUs 102a, 102b, 102c, managing and storing contexts of the WTRUs 102a, 102b, 102c, and the like.

The SGW 164 may be connected to the PGW 166, which may provide the WTRUs 102a, 102b, 102c with access to packet-switched networks, such as the Internet 110, to facilitate communications between the WTRUs 102a, 102b, 102c and IP-enabled devices.

The CN 106 may facilitate communications with other networks. For example, the CN 106 may provide the WTRUs 102a, 102b, 102c with access to circuit-switched networks, such as the PSTN 108, to facilitate communications between the WTRUs 102a, 102b, 102c and traditional land-line communications devices. For example, the CN 106 may include, or may communicate with, an IP gateway (e.g., an IP multimedia subsystem (IMS) server) that serves as an interface between the CN 106 and the PSTN 108. In addition, the CN 106 may provide the WTRUs 102a, 102b, 102c with access to the other networks 112, which may include other wired and/or wireless networks that are owned and/or operated by other service providers.

Although the WTRU is described in FIGS. 1A-1D as a wireless terminal, it is contemplated that in certain representative embodiments that such a terminal may use (e.g., temporarily or permanently) wired communication interfaces with the communication network.

In representative embodiments, the other network 112 may be a WLAN.

A WLAN in Infrastructure Basic Service Set (BSS) mode may have an Access Point (AP) for the BSS and one or more stations (STAs) associated with the AP. The AP may have an access or an interface to a Distribution System (DS) or another type of wired/wireless network that carries traffic in to and/or out of the BSS. Traffic to STAs that originates from outside the BSS may arrive through the AP and may be delivered to the STAs. Traffic originating from STAs to destinations outside the BSS may be sent to the AP to be delivered to respective destinations. Traffic between STAs within the BSS may be sent through the AP, for example, where the source STA may send traffic to the AP and the AP may deliver the traffic to the destination STA. The traffic between STAs within a BSS may be considered and/or referred to as peer-to-peer traffic. The peer-to-peer traffic may be sent between (e.g., directly between) the source and destination STAs with a direct link setup (DLS). In certain representative embodiments, the DLS may use an 802.11e DLS or an 802.11z tunneled DLS (TDLS). A WLAN using an Independent BSS (IBSS) mode may not have an AP, and the STAs (e.g., all of the STAs) within or using the IBSS may communicate directly with each other. The IBSS mode of communication may sometimes be referred to herein as an “ad-hoc” mode of communication.

When using the 802.11ac infrastructure mode of operation or a similar mode of operations, the AP may transmit a beacon on a fixed channel, such as a primary channel. The primary channel may be a fixed width (e.g., 20 MHz wide bandwidth) or a dynamically set width via signaling. The primary channel may be the operating channel of the BSS and may be used by the STAs to establish a connection with the AP. In certain representative embodiments, Carrier Sense Multiple Access with Collision Avoidance (CSMA/CA) may be implemented, for example in in 802.11 systems. For CSMA/CA, the STAs (e.g., every STA), including the AP, may sense the primary channel. If the primary channel is sensed/detected and/or determined to be busy by a particular STA, the particular STA may back off. One STA (e.g., only one station) may transmit at any given time in a given BSS.

High Throughput (HT) STAs may use a 40 MHz wide channel for communication, for example, via a combination of the primary 20 MHz channel with an adjacent or nonadjacent 20 MHz channel to form a 40 MHz wide channel.

Very High Throughput (VHT) STAs may support 20 MHz, 40 MHz, 80 MHz, and/or 160 MHz wide channels. The 40 MHz, and/or 80 MHz, channels may be formed by combining contiguous 20 MHz channels. A 160 MHz channel may be formed by combining 8 contiguous 20 MHz channels, or by combining two non-contiguous 80 MHz channels, which may be referred to as an 80+80 configuration. For the 80+80 configuration, the data, after channel encoding, may be passed through a segment parser that may divide the data into two streams. Inverse Fast Fourier Transform (IFFT) processing, and time domain processing, may be done on each stream separately. The streams may be mapped on to the two 80 MHz channels, and the data may be transmitted by a transmitting STA. At the receiver of the receiving STA, the above described operation for the 80+80 configuration may be reversed, and the combined data may be sent to the Medium Access Control (MAC).

Sub 1 GHz modes of operation are supported by 802.11af and 802.11ah. The channel operating bandwidths, and carriers, are reduced in 802.11af and 802.11ah relative to those used in 802.11n, and 802.11ac. 802.11af supports 5 MHz, 10 MHz and 20 MHz bandwidths in the TV White Space (TVWS) spectrum, and 802.11ah supports 1 MHz, 2 MHz, 4 MHz, 8 MHz, and 16 MHz bandwidths using non-TVWS spectrum. According to a representative embodiment, 802.11ah may support Meter Type Control/Machine-Type Communications, such as MTC devices in a macro coverage area. MTC devices may have certain capabilities, for example, limited capabilities including support for (e.g., only support for) certain and/or limited bandwidths. The MTC devices may include a battery with a battery life above a threshold (e.g., to maintain a very long battery life).

WLAN systems, which may support multiple channels, and channel bandwidths, such as 802.11n, 802.11ac, 802.11af, and 802.11ah, include a channel which may be designated as the primary channel. The primary channel may have a bandwidth equal to the largest common operating bandwidth supported by all STAs in the BSS. The bandwidth of the primary channel may be set and/or limited by a STA, from among all STAs in operating in a BSS, which supports the smallest bandwidth operating mode. In the example of 802.11ah, the primary channel may be 1 MHz wide for STAs (e.g., MTC type devices) that support (e.g., only support) a 1 MHz mode, even if the AP, and other STAs in the BSS support 2 MHz, 4 MHz, 8 MHz, 16 MHz, and/or other channel bandwidth operating modes. Carrier sensing and/or Network Allocation Vector (NAV) settings may depend on the status of the primary channel. If the primary channel is busy, for example, due to a STA (which supports only a 1 MHz operating mode), transmitting to the AP, the entire available frequency bands may be considered busy even though a majority of the frequency bands remains idle and may be available.

In the United States, the available frequency bands, which may be used by 802.11ah, are from 902 MHz to 928 MHz. In Korea, the available frequency bands are from 917.5 MHz to 923.5 MHz. In Japan, the available frequency bands are from 916.5 MHz to 927.5 MHz. The total bandwidth available for 802.11ah is 6 MHz to 26 MHz depending on the country code.

FIG. 1D is a system diagram illustrating the RAN 113 and the CN 115 according to an embodiment. As noted above, the RAN 113 may employ an NR radio technology to communicate with the WTRUs 102a, 102b, 102c over the air interface 116. The RAN 113 may also be in communication with the CN 115.

The RAN 113 may include gNBs 180a, 180b, 180c, though it will be appreciated that the RAN 113 may include any number of gNBs while remaining consistent with an embodiment. The gNBs 180a, 180b, 180c may each include one or more transceivers for communicating with the WTRUs 102a, 102b, 102c over the air interface 116. In one embodiment, the gNBs 180a, 180b, 180c may implement MIMO technology. For example, gNBs 180a, 108b may utilize beamforming to transmit signals to and/or receive signals from the gNBs 180a, 180b, 180c. Thus, the gNB 180a, for example, may use multiple antennas to transmit wireless signals to, and/or receive wireless signals from, the WTRU 102a. In an embodiment, the gNBs 180a, 180b, 180c may implement carrier aggregation technology. For example, the gNB 180a may transmit multiple component carriers to the WTRU 102a (not shown). A subset of these component carriers may be on unlicensed spectrum while the remaining component carriers may be on licensed spectrum. In an embodiment, the gNBs 180a, 180b, 180c may implement Coordinated Multi-Point (COMP) technology. For example, WTRU 102a may receive coordinated transmissions from gNB 180a and gNB 180b (and/or gNB 180c).

The WTRUs 102a, 102b, 102c may communicate with gNBs 180a, 180b, 180c using transmissions associated with a scalable numerology. For example, the OFDM symbol spacing and/or OFDM subcarrier spacing may vary for different transmissions, different cells, and/or different portions of the wireless transmission spectrum. The WTRUs 102a, 102b, 102c may communicate with gNBs 180a, 180b, 180c using subframe or transmission time intervals (TTIs) of various or scalable lengths (e.g., containing varying number of OFDM symbols and/or lasting varying lengths of absolute time).

The gNBs 180a, 180b, 180c may be configured to communicate with the WTRUs 102a, 102b, 102c in a standalone configuration and/or a non-standalone configuration. In the standalone configuration, WTRUs 102a, 102b, 102c may communicate with gNBs 180a, 180b, 180c without also accessing other RANs (e.g., such as eNode-Bs 160a, 160b, 160c). In the standalone configuration, WTRUs 102a, 102b, 102c may utilize one or more of gNBs 180a, 180b, 180c as a mobility anchor point. In the standalone configuration, WTRUs 102a, 102b, 102c may communicate with gNBs 180a, 180b, 180c using signals in an unlicensed band. In a non-standalone configuration WTRUs 102a, 102b, 102c may communicate with/connect to gNBs 180a, 180b, 180c while also communicating with/connecting to another RAN such as eNode-Bs 160a, 160b, 160c. For example, WTRUs 102a, 102b, 102c may implement DC principles to communicate with one or more gNBs 180a, 180b, 180c and one or more eNode-Bs 160a, 160b, 160c substantially simultaneously. In the non-standalone configuration, eNode-Bs 160a, 160b, 160c may serve as a mobility anchor for WTRUs 102a, 102b, 102c and gNBs 180a, 180b, 180c may provide additional coverage and/or throughput for servicing WTRUs 102a, 102b, 102c.

Each of the gNBs 180a, 180b, 180c may be associated with a particular cell (not shown) and may be configured to handle radio resource management decisions, handover decisions, scheduling of users in the UL and/or DL, support of network slicing, dual connectivity, interworking between NR and E-UTRA, routing of user plane data towards User Plane Function (UPF) 184a, 184b, routing of control plane information towards Access and Mobility Management Function (AMF) 182a, 182b and the like. As shown in FIG. 1D, the gNBs 180a, 180b, 180c may communicate with one another over an Xn interface.

The CN 115 shown in FIG. 1D may include at least one AMF 182a, 182b, at least one UPF 184a, 184b, at least one Session Management Function (SMF) 183a, 183b, and possibly a Data Network (DN) 185a, 185b. While each of the foregoing elements are depicted as part of the CN 115, it will be appreciated that any of these elements may be owned and/or operated by an entity other than the CN operator.

The AMF 182a, 182b may be connected to one or more of the gNBs 180a, 180b, 180c in the RAN 113 via an N2 interface and may serve as a control node. For example, the AMF 182a, 182b may be responsible for authenticating users of the WTRUs 102a, 102b, 102c, support for network slicing (e.g., handling of different PDU sessions with different requirements), selecting a particular SMF 183a, 183b, management of the registration area, termination of NAS signaling, mobility management, and the like. Network slicing may be used by the AMF 182a, 182b in order to customize CN support for WTRUs 102a, 102b, 102c based on the types of services being utilized WTRUs 102a, 102b, 102c. For example, different network slices may be established for different use cases such as services relying on ultra-reliable low latency (URLLC) access, services relying on enhanced massive mobile broadband (eMBB) access, services for machine type communication (MTC) access, and/or the like. The AMF 162 may provide a control plane function for switching between the RAN 113 and other RANs (not shown) that employ other radio technologies, such as LTE, LTE-A, LTE-A Pro, and/or non-3GPP access technologies such as WiFi.

The SMF 183a, 183b may be connected to an AMF 182a, 182b in the CN 115 via an N11 interface. The SMF 183a, 183b may also be connected to a UPF 184a, 184b in the CN 115 via an N4 interface. The SMF 183a, 183b may select and control the UPF 184a, 184b and configure the routing of traffic through the UPF 184a, 184b. The SMF 183a, 183b may perform other functions, such as managing and allocating UE IP address, managing PDU sessions, controlling policy enforcement and QoS, providing downlink data notifications, and the like. A PDU session type may be IP-based, non-IP based, Ethernet-based, and the like.

The UPF 184a, 184b may be connected to one or more of the gNBs 180a, 180b, 180c in the RAN 113 via an N3 interface, which may provide the WTRUs 102a, 102b, 102c with access to packet-switched networks, such as the Internet 110, to facilitate communications between the WTRUs 102a, 102b, 102c and IP-enabled devices. The UPF 184, 184b may perform other functions, such as routing and forwarding packets, enforcing user plane policies, supporting multi-homed PDU sessions, handling user plane QoS, buffering downlink packets, providing mobility anchoring, and the like.

The CN 115 may facilitate communications with other networks. For example, the CN 115 may include, or may communicate with, an IP gateway (e.g., an IP multimedia subsystem (IMS) server) that serves as an interface between the CN 115 and the PSTN 108. In addition, the CN 115 may provide the WTRUs 102a, 102b, 102c with access to the other networks 112, which may include other wired and/or wireless networks that are owned and/or operated by other service providers. In one embodiment, the WTRUs 102a, 102b, 102c may be connected to a local Data Network (DN) 185a, 185b through the UPF 184a, 184b via the N3 interface to the UPF 184a, 184b and an N6 interface between the UPF 184a, 184b and the DN 185a, 185b.

In view of FIGS. 1A-1D, and the corresponding description of FIGS. 1A-1D, one or more, or all, of the functions described herein with regard to one or more of: WTRU 102a-d, Base Station 114a-b, eNode-B 160a-c, MME 162, SGW 164, PGW 166, gNB 180a-c, AMF 182a-ab, UPF 184a-b, SMF 183a-b, DN 185a-b, and/or any other device(s) described herein, may be performed by one or more emulation devices (not shown). The emulation devices may be one or more devices configured to emulate one or more, or all, of the functions described herein. For example, the emulation devices may be used to test other devices and/or to simulate network and/or WTRU functions.

The emulation devices may be designed to implement one or more tests of other devices in a lab environment and/or in an operator network environment. For example, the one or more emulation devices may perform the one or more, or all, functions while being fully or partially implemented and/or deployed as part of a wired and/or wireless communication network in order to test other devices within the communication network. The one or more emulation devices may perform the one or more, or all, functions while being temporarily implemented/deployed as part of a wired and/or wireless communication network. The emulation device may be directly coupled to another device for purposes of testing and/or may perform testing using over-the-air wireless communications.

The one or more emulation devices may perform the one or more, including all, functions while not being implemented/deployed as part of a wired and/or wireless communication network. For example, the emulation devices may be utilized in a testing scenario in a testing laboratory and/or a non-deployed (e.g., testing) wired and/or wireless communication network in order to implement testing of one or more components. The one or more emulation devices may be test equipment. Direct RF coupling and/or wireless communications via RF circuitry (e.g., which may include one or more antennas) may be used by the emulation devices to transmit and/or receive data.

Described herein are methods, apparatuses, and/or systems to enable HARQ compatible polar codes for multi-kernel construction of polar codes. Methods, apparatuses, and/or systems herein may include signaling for decoding failure and/or an undecoded information set, methods to select new multi-kernel ordering for the retransmissions, and/or mapping of undecoded information bits to the encoder inputs.

Methods, apparatuses, and/or systems are provided for informing a transmitter about a decoding failure. Methods, apparatuses, and/or systems are provided for updating the set of undecoded information bits and/or corresponding reliabilities based on previous transmissions. Methods, apparatuses, and/or systems are provided for selecting a new ordering for the multi-kernel structure based on the new retransmission code rate. Methods, apparatuses, and/or systems are provided for selecting the information bits with weakest reliabilities in the undecoded set according to the new code rate. Methods, apparatuses, and/or systems are provided for mapping the selected information bits to encoder inputs that has the strongest reliabilities.

HARQ mechanisms for polar codes may not be addressed in existing specifications since control channels (e.g., 5G NR control channels) may not make use of retransmissions. The encoding structure of polar codes may limit the flexibility of one or more HARQ mechanisms that can be used alongside polar decoding process. In examples, methods, apparatuses, and/or systems for multi-kernel polar codes that include HARQ support of polar codes may be described herein.

Methods, apparatuses, and/or systems described herein may be related to multi-kernel Polar codes and/or Hybrid-ARQ systems. Polar Codes and Multi-Kernel Construction may be described herein. Polar codes may be deterministic channel codes that are capacity achieving. Polar codes may show comparable performance to conventional LDPC code and/or turbo code with low or no error floors when aided by the embedded CRC. In examples, polar codes may perform reliably in short block length, as well as medium and long block lengths. Polar codes may be the channel coding scheme for control channels (e.g., of one or more 3GPP NR standards).

Polar code encoding may be defined by equation 1.

$$i . x = {uG}_{N} \qquad ( 1 )$$

The codeword vector may be represented by x. The input vector may be represented by u. The generator matrix may be denoted as G_{N}. The codeword vector of a polar code, x, may be generated by the product of the input vector, u, and the generator matrix, G_{N}. In examples of polar code construction, x and u may be binary vectors with length N=2ⁿ. N may denote the codeword block-length. The generator matrix G_{N} may be defined by the Kronecker power of

$${T}_{2} = [ \begin{matrix}1 & 0 \\ 1 & 1\end{matrix} ] , {G}_{N} = {T}^{⊗ n}$$

where ⊗ n stands for n-th Kronecker power of T.

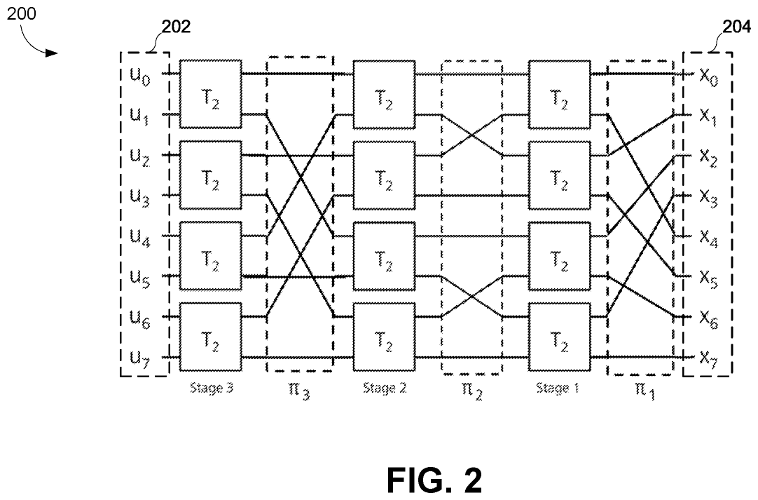

FIG. 2 is a diagram depicting an example polar encoder 200. The polar encoder 200 may have a block length of 8. Polar code encoding may be expressed by the equation x=uG_{N}. The codeword vector may be x 204 (e.g., u0, u1, u2, u3, u4, u5, u6, u7). The input vector may be u 202 (e.g., x0, x1, x2, x3, x4, x5, x6, x7). The generator matrix may be denoted as G_{N}. The codeword vector of polar code, x 204, may be generated by the product of the input vector u 202 and generator matrix, G_{N}. In examples of polar code construction, x 204 and u 202 may be binary vectors with length N=2ⁿ. N may denote the codeword block-length. The generator matrix G_{N} may be defined by the Kronecker power of

$${T}_{2} = [ \begin{matrix}1 & 0 \\ 1 & 1\end{matrix} ] ,$$

G_{N}=T^{⊗n} where ⊗ n stands for n-th Kronecker power of T. The generator matrix G_{N} may be decomposed into multiple consecutive segments where each segment includes a kernel matrix multiplications stage and permutations πᵢ.

One or more input bits for polar code may have a fixed value (e.g., such as zero). Fixed value bits may be called “frozen bits”. The input indexes for frozen bits may be represented by the set

$${A}^{c} = \{ {a}_{1}^{c} , {a}_{2}^{c} , {a}_{3}^{c} , ... , {a}_{N - K}^{c} \}$$

and/or

$${a}_{i}^{c} < {a}_{j}^{c} if i < j .$$

The remaining part of input bits for polar code may convey variable information and/or may be called “unfrozen bits”. The input indexes for unfrozen bits may be represented by the set A={a₁, a₂, a₃ . . . , a_{K}} and aᵢ<aⱼ if i<j.

The number of information bits (e.g., or unfrozen bits) may be described as K. The codeword block length may be N. The number of frozen bits may be described as N-K. The code rate of a polar code may be denoted as R. The code rate of a polar code, R, may be described as K/N.

Code construction may be described herein. Code construction may be a process of determining the input bit indexes between the frozen bits and unfrozen bits for polar codes. Code construction may comprise initially calculating the reliability of each input bit index, and/or ordering bit index reliabilities (e.g., before starting the encoding operation). If a bit index reliability order is determined, in examples, the least reliable input bits may be assigned as frozen bits and the remaining bits may be assigned as unfrozen/information bits. The ratio of frozen and unfrozen bits may be determined according to the desired code rate.

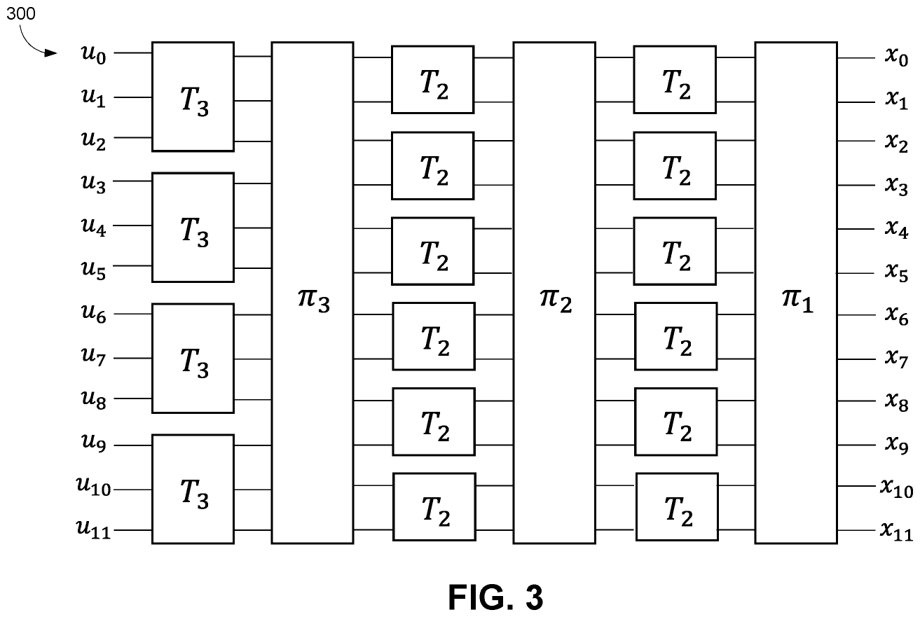

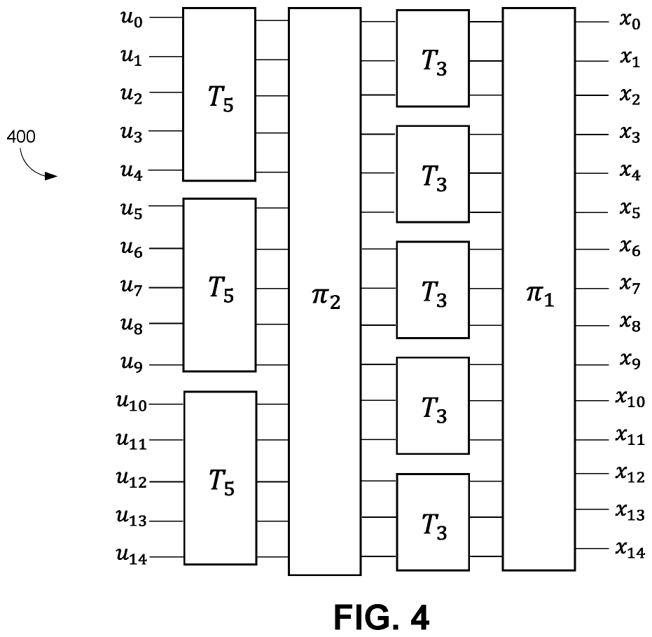

FIG. 3 is a diagram depicting an example multi-kernel polar encoder 300 with a codeword size 12. FIG. 4 is a diagram depicting an example multi-kernel polar encoder 400 with a codeword size 15.

Multi-kernel polar codes may provide flexible code rates. In examples, multi-kernel polar codes may provide more flexible code rates compared to polar codes with 2×2 kernels. Multi-kernel polar codes may use 2×2 kernels. Multi-kernel polar codes may use kernels of types different than 2×2. For example, multi-kernel polar codes may use 3×3, 5×5, and/or 7×7 kernels, or a combination of these kernels. Some examples of these kernels may be provided by the matrices T₂, T₃, and T₅.

$${T}_{2} = [ \begin{matrix}1 & 0 \\ 1 & 1\end{matrix} ] , {T}_{3} = [ \begin{matrix}1 & 0 & 0 \\ 1 & 1 & 0 \\ 1 & 0 & 1\end{matrix} ] , {T}_{5} = [ \begin{matrix}1 & 0 & 0 & 0 & 0 \\ 1 & 1 & 0 & 0 & 0 \\ 1 & 0 & 1 & 0 & 0 \\ 1 & 0 & 0 & 1 & 0 \\ 1 & 1 & 1 & 0 & 1\end{matrix} ]$$

The multi-kernel structure may be in the form of kernel order, kernel sizes, and/or kernel structure. Kernels with similar size may be obtained differently. For example, FIG. 3 may depict a configuration of a multi-kernel polar encoder construction of T₃×T₂×T₂. The construction of the multi-kernel polar encoder 300 may comprise a codeword size that may be implicitly determined as N=12 (3×2×2). FIG. 4 may depict a configuration of a multi-kernel polar encoder construction of T₅×T₂. The codeword size multi-kernel polar encoder 400 may be N=15.

Hybrid Automatic Repeat Request (HARQ) may be used for ensuring reliable and/or successful transmissions. HARQ with respect to polar codes may be described herein. HARQ may be based on the combination of forward error correction and/or a retransmission strategy (ARQ), that includes enabling retransmissions of codewords (e.g., entire codewords and/or subsets of codewords) until the one or more transmissions are successfully received and/or the maximum number of retransmissions is allowed. If the maximum number of allowed transmissions is reached, the transmission may be erroneous. There may be various HARQ retransmission techniques, wherein the difference between the techniques may be at least in part related to how the retransmitted signals are combined by the receiver, and/or if the entire codeword and/or just a subset of information and/or redundancy bits are retransmitted.

In examples, performance metrics that may be used to evaluate a HARQ scheme (FEC+ARQ) include the average number of retransmissions, spectrum efficiency, and/or average throughput. The average number of retransmissions may play a role in the transmission latency, in some examples irrespective of if the transmission is successful or not. The spectrum efficiency and/or average throughput may be related to the Success Rate (e.g., or inversely BLER), as well as the code-rate and/or modulation order.

One HARQ variant that may be used for communications is the Incremental Redundancy (IR-HARQ). For IR-HARQ, the transmission may start with a higher code-rate. In IR-HARQ examples comprising a retransmission (e.g., when a NACK is received as feedback), a lower code-rate may be employed. A lower code rate may be employed by, for example, adding additional parity bits to the information sequence transmission. In examples, this process may iterate until the codeword is transmitted successfully (e.g., until an ACK is fed back). In examples, a (re) transmission may be successful when a codeword is received properly (e.g., the decoded codeword passes a Cyclic Redundancy Check). For example, a (re) transmission may be determined to be successful when a decoded codeword passes a cyclic redundancy check. In examples, the bits of the transmitted codeword may be received properly by the receiver after the initial transmission, or after one or more retransmissions.

IR-HARQ may help to maintain a relatively higher throughput and/or spectrum efficiency, while employing a similar (e.g., the same) code structure. Puncturing and/or shortening may be used in LDPC codes for supporting the rate-matching that enables the IR-HARQ. Use of puncturing and/or shortening may be in addition to the particular structure of the employed LDPC codes that allows a nested configuration of subsets of parity-check matrices, which may provide the possibility to decode sub-codewords (e.g., using the mother code structure).

Polar coding to support rate-matching and/or IR-HARQ may be described herein. Polar coding to support rate-matching and/or IR-HARQ without a significant performance degradation may be described herein. Polar codes may be structured in nature. In examples, the use of puncturing and/or shortening operations for rate-matching may impact BLER performance. For example, BLER performance degradation may be caused by the unavailability of a nested structure. A nested structure may comprise higher rate codes within a lower rate mother code. In examples, nested code rate structure may be punctured while still having the property of being a good code. A good code may have a BLER performance below a certain threshold, for example, after puncturing. For examples of dual polar codes, there may be no available capability to include identity submatrices in the dual polar code representation in a way that results in one or more (e.g., all) the nested codes having good performance. The codelengths of conventional polar codes may be in the form of powers of 2, which may further reduce the flexibility of polar coding schemes.

Multi-Kernel Polar codes may allow for addressing a limitation of conventional Polar codes in terms of code length flexibility. Achieving rateless Polar codes that can perform well in different rates may not be clear and/or established in the current 3GPP standards.

Rateless LDPC and/or Turbo codes may be enabled by the puncturing procedure, where a mother code with lower code rate may be used. Puncturing a set of the codeword of the mother code's bits and/or transmitting the bits during retransmissions may be performed. The incremental redundancy approach may guarantee that the use of higher code rate codes does not lead to performance degradation. Not leading to performance degradation may be achieved by a special nested structure of the parity-check matrix, which may allow an optimized degree distribution and/or nested properties. For Polar codes, the nested property may be difficult to achieve due to the highly structured nature of these codes. Incremental redundancy by puncturing and/or shortening may not naturally enable strong codes for different rates.

Current implementations, such as Hybrid ARQ, for polar codes which are used for control channels (e.g., in 5G NR) may not include adaptive retransmission procedures. The encoding structure of polar codes may limit the flexibility of HARQ mechanisms that can be used alongside a polar decoding process.

HARQ support for polar codes may be described herein. Polar coding may be used for data channels of future wireless systems. For example, polar coding may be used due to error correction advantages. If polar coding is used for future data channels (e.g., beyond 5G systems), HARQ support capabilities may be resolved. The methods and/or procedures described herein may comprise enablers and/or procedures for the use of HARQ with multi-kernel polar codes. The methods, procedures, and/or devices described herein may address adaptive retransmission procedures for polar codes. Benefits of the methods, procedures, and/or devices described herein may include enablers that combine multi-kernel polar codes and/or IF-HARQ to provide flexible polar coding process towards future (e.g., 6G and follow) communications.

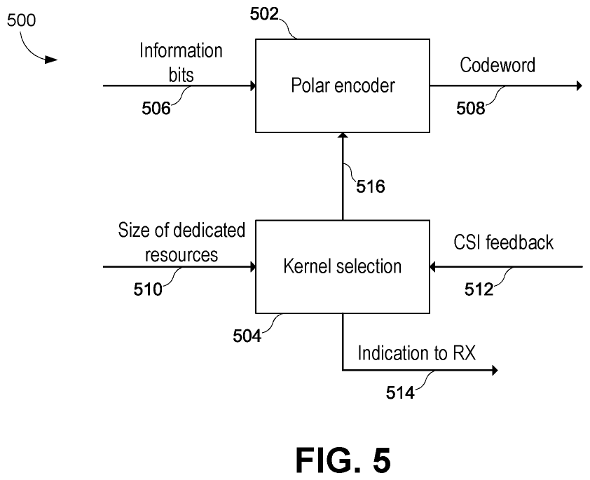

Kernel structure selection for multi-kernel polar codes may be described herein. FIG. 5 is a flow diagram depicting an example multi-kernel polar code framework 500. The multi-kernel polar code framework 500 may comprise enablers and/or signaling for the multi-kernel polar codes to be used in practical communication systems. An encoding device (e.g., such as a WTRU) may comprise the multi-kernel polar code framework 500. The building blocks of the multi-kernel polar code framework 500 may comprise a multi-kernel polar encoder 502 and/or a kernel selection block(s) 504. The multi-kernel polar encoder 502 may be constructed based on the kernel structure output of a kernel selection block 504.

Multi-kernel polar encoding may be described herein. The multi-kernel polar encoder 502 may be constructed based on the configuration inputs 516 from the kernel selection block 504. A polar code kernel structure may be determined by the kernel selection block 504. The encoding device may send an indication 514 to the receiver that indicates the determined polar code kernel structure. The constructed multi-kernel polar encoder 502 may encode the information bits 506 (e.g., using the polar code kernel structure determined by the kernel selection block 504) to output the codeword 508. The configuration input 516 from the kernel selection block 504 may include information about the multi-kernel structure of the polar encoder (e.g., such as the polar code kernel structure) and/or the codeword length. The kernel selection block 504 may determine the output to the polar encoder 516 based on one or more selection criteria inputs. In examples, the kernel selection block 504 may determine the output (e.g., the polar code kernel structure) to the polar encoder 516 based on the size of available resources 510 and CSI feedback 512. A kernel structure indication 518 may be sent to a receiver. For example, the kernel selection block 516 may output the kernel structure indication 518 to the receiver. The kernel structure indication 518 may indicate the kernel structure selected by the kernel selection block 504.

In examples, the transmitter may include a set of kernels that can be used to construct the multi-kernel polar encoder. The set of kernels may be signaled to the receiver (e.g., via the available messaging capability). In examples, the transmitter and/or receiver may be a wireless transmit receive unit (WTRU). The set of available kernels in a WTRU may be denoted as

$$U : \{ {T}_{{i}_{1}} , {T}_{{i}_{2}} , … , {T}_{{i}_{{N}_{U}}} \}$$

where iₖ denotes the size of a kernel in the set comprising N_{U} distinct kernels.

Multi-Kernel Polar Encoding may comprise dynamic selection of an information set. The information set (e.g., the frozen bit set and/or the mapping of information bits to encoder inputs) may be determined as part of the polar code construction process. In examples, the information set may be determined based on the reliabilities of the input bits. For example, the reliabilities of the input bits may be determined based on the density evolution under gaussian approximation (DE/GA) technique. The bit channels with higher reliabilities may be assigned to information symbols. For example, data bits to be transmitted may be mapped to encoder inputs (e.g., bit channels) that have higher (e.g., the strongest) reliabilities. In such examples, the rest of the input bits may be frozen (e.g., assigned the value 0).

In examples, the information set may be determined based on the minimum distance of the multi-kernel structure of the polar codes. The information set may be determined to maximize the minimum distance of the selected information set.

In examples, the information set construction may be based on an indication from a gNB. The WTRU may use the indication from the gNB to determine the information set. The indication may include an index to a pre-defined technique. The indication may include indices of inputs bits to be used as the information set.

The kernel selection block (e.g., such as the kernel selection block 504 shown in FIG. 5) may be used by a WTRU to select a kernel structure. For example, the kernel selection may be performed by the WTRU. In examples, the WTRU may determine and/or select the kernel structure based on parameters such as channel quality and/or size of resources. For example, the channel quality may be measured by the CQI parameter that indicates SNR, code rate R, and/or modulation order Q, for a measured RSSI. For example, size of resources may be the target codeword length, E, and/or the number of dedicated resource elements, N_{RE}. If the size of resources is provided as input, the target codeword length may be computed by E=Q. N_{RE}. The number of information bits, K, may be computed by K=R·E.

Kernel selection may comprise identifying a set of multi-kernel structure candidates. In examples, the multi-kernel structure candidates may be determined based on the target codeword length E. In examples, the kernel selection block may determine the set of candidate kernel structures S_{W}:{W₁, W₂, . . . , W_{N}_{_{C}}} where N_{C} denotes the number of candidate kernel structures, Wⱼ denotes the kernel structure with Wⱼ:Tⱼ_{₁}×Tⱼ_{₂}× . . . ×Tⱼ_{_{M}}ⱼ where Mⱼ denotes the number of stages in j-th kernel structure, Tⱼ_{ₗ} denotes a kernel of size jₗ in kernel structure Wⱼ, Tⱼ_{ₗ}∈U and/or jₗ∈{i₁, i₂, . . . , j_{N}_{_{U}}}, l=1, 2, . . . , Mⱼ. The codeword length for a given kernel structure Wⱼ may be computed by Nⱼ=j₁·j₂· . . . j_{M}_{ₗ}. The set of candidate kernel structures S_{W} may comprise kernel structures with codeword length Nⱼ that are close to the target codeword length E. In examples, Nⱼ∈[E−δ, E+δ], where δ may be an integer satisfying the condition 0<δ<<E. In examples, the value of δ may be indicated to the WTRU and/or pre-determined.

Kernel selection (e.g., the kernel selection block) may include computing one or a set of performance metric(s) for one or more (e.g., all) candidate kernel structures in the set S_{W}. In examples, the performance metric Pⱼ may be a function of the SNR, code rate R, the kernel structure Wⱼ and/or target code rate E, so that Pⱼ=F(SNR, R, Kⱼ, E) where F( ) may denote a function and/or method to measure the performance of a kernel. Examples of the function to measure the performance may be described herein. In examples, kernel selection may be based on one or more kernel performance metrics such as reliability, encoding complexity, minimal rate matching, and/or distance spectrum.

Kernel performance (e.g., the kernel performance function) may be based on reliability. An average reliability of input bit channels may be used to determine the kernel performance. For a given kernel structure W, and/or SNR, the reliability of each input bit may be computed. In examples, the bit channel reliabilities may be calculated based on a DE/GA technique. The mean of the highest K reliabilities may be computed to obtain Pⱼ, where K=R·Nⱼ. In examples, a higher Pⱼ may imply better performance.

Kernel performance (e.g., the kernel performance function) may be based on encoding complexity. Encoding complexity of a multi-kernel polar encoder may be used to determine the kernel performance. For a given kernel structure Wⱼ, the number of XOR operations may be determined based on the kernels in the structure. In examples, Oⱼ may denote the number of XOR operations included for a kernel Tⱼ. For example, for a given kernel structure Wⱼ, the performance may be determined as

$${P}_{j} = \frac{{N}_{j}}{{j}_{1}} {O}_{{j}_{1}} + \frac{{N}_{j}}{{j}_{2}} {O}_{{j}_{2}} + ⋯ + \frac{{N}_{j}}{{j}_{{M}_{j}}} {O}_{{j}_{{M}_{j}}} .$$

In examples, a lower Pⱼ may imply better performance.

Kernel performance (e.g., the kernel performance function) may be based on distance spectrum. The distance spectrum of a kernel structure may be used as a performance function to select the kernel structure. In examples, a kernel T, may have an associated partial distance sequence D_{T}_{ₗ}: (D₁, D₂, . . . . Dₗ), where Dᵢ denotes the number of non-zero entries in the i-th row of Tᵢ. For example, the partial distance sequence for a kernel T₂ may be given by D_{T}_{ₗ}:(1,2). The partial distance sequence for kernel T₃ may be given by D_{T}_{ₗ}:(1,2,2). The distance spectrum of a kernel structure

$${W}_{j} : {T}_{{j}_{1}} \times {T}_{{j}_{2}} \times ⋯ \times {T}_{{j}_{{M}_{j}}}$$

may be computed by

$${D}_{{W}_{j}} : {D}_{{T}_{{j}_{1}}} ⊗ {D}_{{T}_{{j}_{2}}} ⊗ … ⊗ {D}_{{T}_{{j}_{{M}_{j}}}} .$$

For example, assuming Wⱼ:T₃×T₂, then, D_{W}_{ⱼ}:(1,2,2)⊗(1,2)=(1,2,2,4,2,4). The distance spectrum may be used within a performance function to select the strongest kernel. For example, the mean of D_{W}_{ⱼ} may be computed to obtain Pⱼ.

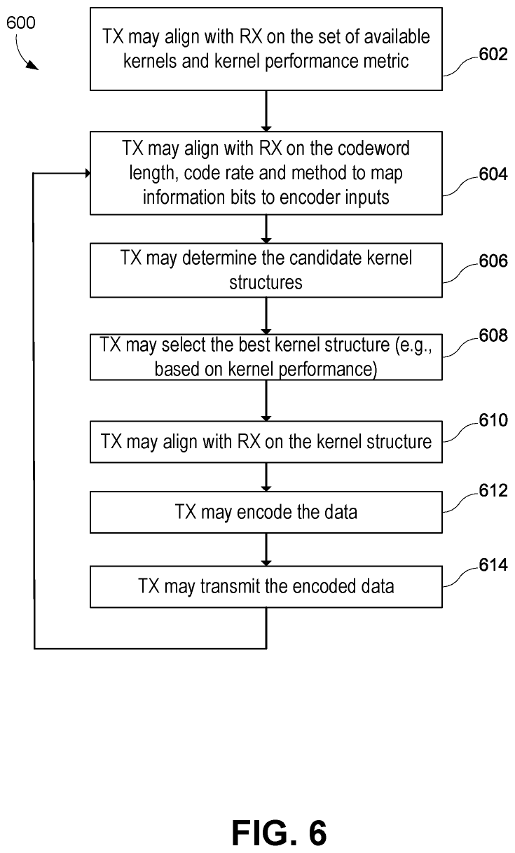

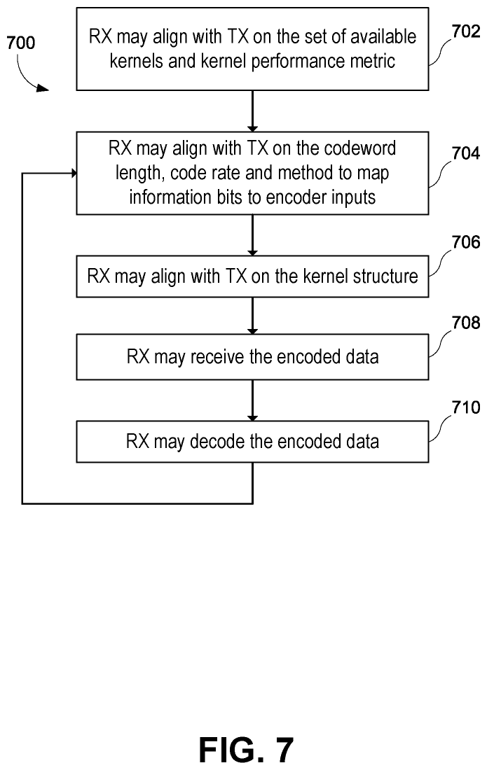

Kernel selection (e.g., the kernel selection block) may select the strongest kernel structure to be used, for example, based on the kernel performance (e.g., the kernel performance function). The selected kernel and/or K may be fed to the Polar Encoder for the encoding process. The selected kernel structure may be signaled to the receiver. An example multi-kernel selection process 600 of a transmitter is depicted in FIG. 6. An example multi-kernel selection process 700 of a receiver is depicted in FIG. 7. The selected kernel structure may be a multi-kernel structure selected based on the kernel performance function, wherein the kernel performance function may be used to select the kernel structure based on one or more performance metrics.

FIG. 6 is a flowchart depicting an example multi-kernel encoding process 600 at a transmitter. At 602, the transmitter may align with the receiver on a set of available kernels and/or a kernel performance metric to be used for kernel selection. For example, the transmitter may receive, at 602, a set of available kernels from the receiver within a capability signaling message (e.g., as part of an alignment process between the transmitter and the receiver). At 604, the transmitter may align with the receiver on a codeword length, a code rate, and/or a mapping of information bits to encoder inputs. For example, the transmitter may send, at 604, an indication that indicates a codeword length, a code rate, and/or a method of mapping information bits to encoder inputs to the receiver (e.g., as part of an alignment process between the transmitter and the receiver). At 606, the transmitter may determine the candidate kernel structures. At 608, the transmitter may select the kernel structure. In examples, the kernel structure may be selected based on a determined metric (e.g., based on kernel performance). For example, the transmitter may utilize at 608 the kernel performance function to select an appropriate kernel structure. At 610, the transmitter may align with the receiver on the selected kernel structure. The transmitter may indicate the determined kernel structure to the receiver (e.g., as part of an alignment process between the transmitter and the receiver). At 612, the transmitter may encode the data to be transmitted via multi-kernel encoding. The data encoded at 612 may be performed using the selected kernel structure (e.g., the multi-kernel structure selected at 608). At 614, the transmitter may transmit the encoded data to the receiver. After each transmission transmitted at 614, the multi-kernel encoding process 600 may return to 604 so that the transmitter may align with the receiver on a codeword length, a code rate, and/or a mapping of information bits to encoder inputs associated with another transmission.

FIG. 7 is a flowchart depicting an example multi-kernel encoding process 700 at the receiver. At 702, the receiver may align with the transmitter on the set of available kernels and/or a determined kernel performance metric. For example, the receiver may report, at 702, an available set of kernels to the transmitter within a capability signaling message (e.g., as part of an alignment process between the transmitter and the receiver). At 704, the receiver may align with the transmitter on a codeword length, a code rate, and/or a method to map information bits to encoder inputs. For example, the receiver may receive, at 704, an indication that indicates a codeword length, a code rate, and/or a method of mapping information bits to encoder inputs from the transmitter (e.g., as part of an alignment process between the transmitter and the receiver). At 706, the receiver may align with the transmitter on the determined and/or selected kernel structure. For example, the receiver may receive, at 706, an indication from the transmitter of the selected kernel structure. At 708, the receiver may receive the encoded data. At 710, the receiver may decode the encoded data. After decoding each set of received encoded data at 710, the multi-kernel encoding process 700 may return to 704 so that the transmitter may align with the receiver on a codeword length, a code rate, and/or a mapping of information bits to encoder inputs associated with another transmission (e.g., set of encoded data).

In examples, the WTRU and gNB may include procedures for the fallback to a legacy 2x2 kernel structure for polar coding. For example, the fallback may be triggered by the gNB and/or indicated to the WTRU based on factors such as the number of WTRUs served by the gNB, traffic load, channel status, available computation resources, etc. In examples, the fallback may be triggered by the WTRU based on factors such as available computation resources, channel status, battery status, throughput, etc. In examples, the fallback may be triggered implicitly by the WTRU and/or gNB based on factors such as channel status, throughput, etc.

A multi-kernel polar decoder may be a receiver (e.g., WTRU or gNB based on DL or UL). A multi-kernel polar decoder may include one or more modules for the decoding of multi-kernel polar codes. The decoder may be built on the selected multi-kernel structure. The decoder may be of type successive cancellation decoder, belief propagation decoder, and/or AI/ML based decoder, etc. In examples, the decoder may be of type blind decoder without the knowledge of the multi-kernel structure. The receiver may or may not recover the multi-kernel structure as part of the decoding process.

Signalling may enable the multi-kernel structure selection process. In examples, a WTRU and a gNB may signal between one another. A WTRU and a gNB may signal between one another to align on a set of available kernels, align on a selected kernel structure, determine the method of kernel structure selection, select the information set, and/or engage in fallback procedures. In examples, signaling between the WTRU and the gNB may be based on control or data channels.

Signalling may be utilized for a WTRU and a gNB to align on a set of available kernel structures. The WTRU may feedback available kernels as part of a capability signaling. In examples, feedback on the set of available kernels may include the indices of available kernels. In examples, the WTRU may feedback the index of kernel structures that may be pre-defined to both the WTRU and the gNB. In examples, the set of kernels may be pre-defined and/or implicit to the WTRU and the gNB. In examples, one kernel structure and/or a set of kernel structures may be determined flexibly by the WTRU, and/or reported to the gNB, periodically, semi-periodically, or dynamically (e.g., the set U). In examples, the gNB may indicate a set of kernels to the WTRU.

Signaling may related to the selected kernel structure. The WTRU and gNB may be aligned on the selected kernel structure. The feedback on the kernel structure may include the size of one or more (e.g., all) selected kernel structures and/or indices of the selected kernel structures. In examples, the selected kernel structure may be implicit to the WTRU and gNB for a set of parameters such as SNR, code R, and/or target codeword length E. In examples, the set of parameters may be known by the WTRU and gNB.

Signalling may be related to the kernel structure selection process. In examples, the WTRU may determine a kernel selection method based on the WTRU's current status, scenario, historical information, etc. If the kernel structure is explicit, the WTRU and gNB may be aligned via signaling on the kernel selection method. If the kernel structure feedback is implicit, there may be no explicit signaling between the WTRU and gNB for alignment. In examples, the kernel selection method may be indicated by the gNB to the WTRU, for example, by sending an index to the WTRU from a pre-defined table of kernel selection methods. In examples, the WTRU may feedback the identified kernel selection method to gNB. For example, the WTRU may feedback the kernel selection method by sending an index from a pre-defined table of kernel selection methods. In examples, the WTRU may flexibly determine and/or signal the kernel selection method.

Signaling may be related to the selection of information set(s). In examples, the WTRU and gNB may align on the technique used for the selection of the information set. In examples, the techniques used for the selection of information set may be pre-defined at the WTRU and/or the gNB. The gNB may indicate the technique to be used to the WTRU. In examples, the gNB and/or WTRU may indicate the indices of information set. In examples, the indication of the information set may be implicit based on parameters such as codeword length and SNR.

Signaling may be related to fallback procedures. In examples, the gNB may indicate a fallback to the legacy kernel to the WTRU. In examples, the WTRU may feedback to the gNB a request to fallback to the legacy kernel structure that may be followed by an approval indication from the gNB to the WTRU.

Signaling (e.g., between a WTRU and a gNB) may be based on control and/or data channels, dynamically and/or semi-statically. For example, signalling may occur via UCI over PUCCH/PUSCH, DCI over PDCCH, and/or MAC CE. The implicit signalling between the WTRU and gNB may include selection of certain UL resources for control and/or data. For example, implicit signalling may comprise a selection of a specific PUCCH resource, RACH resources, SRS resource, spatial relation Info, etc.

Initial configurations for multi-kernel polar coding may be described herein. In examples, the WTRU may feedback a set of available kernels to gNB via the signalling capabilities. The WTRU may receive an indication of a kernel performance metric. The kernel performance metric may be related to (e.g., provide a basis for) the kernel performance function. In examples, the kernel performance metric may be used for code blocks (e.g., all code blocks). The WTRU may receive an indication of a retransmission scheme including intermediate code rates and/or updated kernel structures to be used in case of retransmissions. The WTRU may receive an indication of a method that maps the information bits to encoder inputs.

A multi-kernel structure may be selected. The WTRU may receive an indication of the available resources, codeword size, code rate, and/or kernel structure (e.g., multi-kernel structure). The WTRU may determine the set of candidate kernel structures based on the allocated resources and/or codeword length for a given kernel structure. The WTRU may determine a performance metric to select a kernel structure (e.g., choose among methods based on complexity, reliability, distance spectrum and/or minimal rate matching). The WTRU may compute the performance metric of one or more (e.g., all) candidate kernels. The WTRU may feed the kernel structure to the multi-kernel polar encoder.

Encoding/decoding may be performed using a multi-kernel polar encoder. A WTRU may receive a code block encoded via a multi-kernel polar code. The WTRU may construct the multi-kernel polar encoder with the provided kernel structure from the kernel selection block. The WTRU may map data bits to bit channels (e.g., multi-kernel polar encoder inputs) based on the given mapping method and/or code rate. The WTRU may encode the information bits and/or generate codeword. The WTRU may decode the code block to recover information bits.

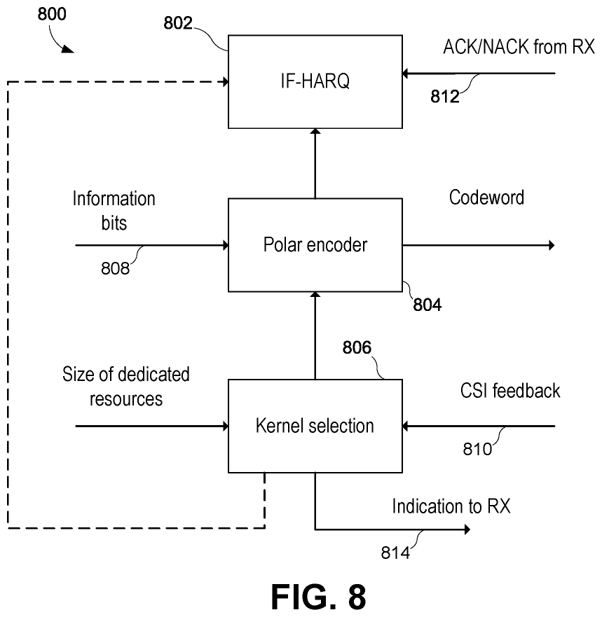

FIG. 8 is a diagram depicting an example Incremental Freezing HARQ (IF-HARQ) enabled multi-kernel polar framework 800. An encoding device (e.g., such as a WTRU) may comprise the IF-HARQ enabled multi-kernel polar code framework 800. The multi-kernel polar encoder 800 may include a polar encoder 804. The polar encoder 804 may encode data bits using a polar code associated with a polar code kernel structure. The polar encoder 804 may utilize a polarization effect. The polarization effect may be described by circumstances when information bits 808 are attributed to noiseless bit channels and/or frozen bits are transmitted through low reliability bit channels. Incremental freezing may be a rate-matching technique that may preserve the capacity-achieving property of polar codes in different regimes while supporting the HARQ process. Incremental freezing may be used in multi-kernel polar encoding to enable IF-HARQ 802. For example, instead of incremental redundancy. Enabling IF-HARQ 802 may comprise freezing less bits initially, enabling a high code rate, and/or progressively retransmitting (e.g., via an initial transmission and a number of retransmissions) information bits being previously transmitted in less reliable channels. Retransmitted bits decoded in future transmissions may result in an effective freezing of bits and/or allowing of information bits sent on the first transmission to be decoded. In examples, the freezing process may converge. The freezing process may converge, for example, if the frozen set of information bits is selected based on reliability ordering of bit channels. Incrementally freezing bits sent in earlier (re) transmissions may preserve the capacity-achieving feature of polar codes. Multi-kernel polar code kernel structures may be used to support different codelengths.

For enabling IF-HARQ 802 using multi-kernel polar code kernel structures, the WTRU may be configured to transmit/receive CSI feedback 810 and/or to signal the target information block length K before transmission. The kernel selection block 806 may select a polar code kernel structure. The encoding device may send an indication 814 to the receiver that indicates the selected polar code kernel structure. After selecting an appropriate polar code kernel structure, in examples, the initial (e.g., peak) code rate R₀ may be determined based on the MCS index provided by the link adapter. For example, the WTRU may determine the initial code rate R₀ (e.g., for an initial data transmission) based on the MCS index. In examples, the information and frozen set selection process may depend on the peak code rate, codeword length and/or kernel structure.

A WTRU may receive a plurality of multi-kernel polar coding configurations (e.g., from the network or another WTRU). A multi-kernel polar coding configuration may be a multi-kernel polar code kernel structure. A multi-kernel polar coding configuration may comprise a mapping of information bits to encoder inputs. The WTRU may transmit a first data transmission (e.g., a set of polar coded data bits) using a first multi-kernel polar code configuration of the plurality of multi-kernel polar code configurations. For example, the WTRU may encode a set of data bits using the first multi-kernel polar code configurations. The set of data bits may be mapped to a first set of bit channels in the initial transmission based on respective reliabilities of the data bits. The first data transmission may be an initial transmission. The first multi-kernel polar code configuration may be associated with a first polar code kernel structure, a first code rate, and a first codeword length to the network or the other WTRU. The first polar code kernel structure may include a first kernel order, a first kernel size, and/or a first kernel structure. The WTRU may receive feedback 812 in response to the first data transmission (from the network or the other WTRU). The feedback 812 may indicate an acknowledgement (ACK) or a negative ACK (NACK) associated with the initial transmission.

When the feedback 812 indicates a NACK, the WTRU may initiate an IF-HARQ process 802. The NACK may indicate that at least a first subset of the polar coded data bits were not successfully decoded by the receiver. The IF-HARQ process 802 may comprise kernel selection (e.g., the kernel selection block 806), for example, associated with a retransmission (e.g., a first retransmission). The WTRU may determine a second polar code structure. The WTRU may determine a code rate for the first retransmission based on a pre-defined set of code rates and/or a signal to noise ratio associated with the initial transmission. The second polar code structure may be associated with a second multi-kernel polar code configuration, a second code rate, and/or a second codeword length. The second polar code structure may comprise a mapping of a first set of data bits to polar code encoder inputs (e.g., bit channel of the second polar code kernel structure) and a second set of information bits that may be frozen. The first set of information bits may comprise a lower reliability than the second set of information bits. The WTRU may send an indication of the second polar code kernel structure for the first retransmission to the receiver. The WTRU may send the mapping of the first set of data bits to the bit channels of the second polar code kernel structure to the receiver.

The WTRU may retransmit the first data to the network or the other WTRU using the second multi-kernel polar code configuration. For example, the WTRU may encode at least the first subset of the data bits that were not successfully decoded by the receiver using a polar code associated with a second polar code kernel structure. The second polar code kernel structure may include a second kernel order, a second kernel size, and/or a second kernel structure. The first subset of the data bits may be encoded using relatively higher reliability bit channels of the second polar code kernel structure than a reliability associated with a one or more bit channels that were used for encoding the first subset of the data bits using the first polar code kernel structure of the initial transmission. The WTRU may send a first retransmission to the receiver that comprises the first subset of the data bits associated with the second polar code kernel structure.

Methods and/or enablers for dynamic kernel order selection, mapping of information bits to encoder inputs, and/or intermediate code rates may be described herein. If a multi-kernel polar code kernel structure is selected, the transmitter may encode the information bits and/or transmit the information bits through the K most reliable channel bits (e.g., encoder inputs), while the remaining N-K bits may be frozen for the first transmission. A freezing pattern may be identified (e.g., mapping of information bits to encoder inputs) for enabling the IF-HARQ process. The freezing pattern may be identified for retransmissions. Additionally or alternatively, the mapping of information bits to encoder inputs may depend on the intermediate code rates used for the retransmissions.

In examples, dynamic kernel order selection and/or mapping of information bits may be performed for incremental freezing. For multi-kernel polar codes, the order of the kernels may impact the polarization operation, and/or the order of the reliabilities of encoder inputs. Changing the order of kernels in W may be equivalent to permuting its rows and/or columns, given that the Kronecker product may not be commutative.

The IF-HARQ may be achieved with multi-kernel polar codes by subsequently adapting the kernel structure (e.g., dynamically changing the order of the kernels in each retransmission). The resulting permutation may lead to different reliability orders for the channel bits, which may be beneficial for one or more (e.g., some) information bits. IF-HARQ may incrementally freeze channel bits based on their reliability order in different previous transmissions. Changing the order of the kernels may result in a different ranking of reliabilities of encoder inputs, and/or a gain can be obtained by retransmitting least reliable bits from previous transmissions that have a higher reliability after applying the kernel order permutation.

After generating the different kernel orders, for example, the transmitter may calculate the reliabilities of the encoder inputs (e.g., bit channels) of the available multi-kernel polar code kernel structures. The reliabilities may be, for example, determined by the DE/GA technique. In examples, the set ρWⱼ={ρ₁, ρ₂, . . . , ρ_{K}} may denote the K highest reliability scores of information bits in the kernel structure Wⱼ represented with the set A_{W}_{ⱼ}={a₁, a₂, a₃ . . . , a_{K})} where aₖ<aₗ if k<1. The transmitter may select a polar code kernel structure based on the reliability set ρ_{W}_{ⱼ}. In examples, a metric may be defined to take the average of the reliabilities such that

$${P}_{{W}_{j}} = \frac{1}{K} \sum {ρ}_{i} .$$

In examples, the transmitter may select the Wⱼ with the highest P_{W}_{ⱼ}. In examples, a metric that may be included is to determine the reliabilities may be

$${P}_{{W}_{j}} = {min}_{{ρ}_{j} ∈ {ρ}_{{W}_{j}}} {ρ}_{j} .$$

The WTRU may select the Wⱼ with the highest P_{W}_{ⱼ}. Following the selection of the kernel structure, for example, the information bits bᵢ with lowest K reliabilities in the previous transmissions may be assigned to the polar encoder inputs for the new transmission.

In examples, a multi-kernel polar code kernel structure with parameters (N, K)=(12,9) may be generated by the multi-kernel structure (T₂, T₃, T₂) for an initial transmission with a coderate

$${R}_{0} = \frac{3}{4} .$$

The information bits transmitted during the first transmission (b₁, . . . , b₉) may be assigned to encoder inputs based on Table 1 where uᵢ indicates the polar encoder inputs. One or more (e.g., all) other encoder inputs, e.g., u₁, u₂, u₃ may be frozen (e.g., set to 0). The peak code rate and/or intermediate code rates for the retransmissions may be provided as

$$[ {R}_{0} , {R}_{1} , {R}_{2} , {R}_{3} ] = [ \frac{3}{4} , \frac{1}{2} , \frac{1}{4} , \frac{1}{6} ] .$$

TABLE 1
Mapping Information Bits to Encoder Inputs based on
{T₂, T₃, T₂} for a first retransmission.

| Information bits in | | | | | | | | | |
|---|---|---|---|---|---|---|---|---|---|
| 1^{st} transmission | b₁ | b₂ | b₃ | b₄ | b₅ | b₆ | b₇ | b₈ | b₉ |
| Encoder Input | u₄ | u₅ | u₆ | u₇ | u₈ | u₉ | u₁₀ | u₁₁ | u₁₂ |
| Reliability Order | 7 | 8 | 5 | 9 | 6 | 4 | 2 | 3 | 1 |
| (given in Table 2) | | | | | | | | | |
| Reliability | 0.5056 | 0.1914 | 0.6836 | 0.1780 | 0.6658 | 0.7932 | 0.9880 | 0.8789 | 0.9961 |
| (given in Table 2) | | | | | | | | | |

If the first transmission was not successful and/or the transmitter received NACK, the transmitter may compute the reliabilities of encoder inputs for one or more (e.g., all) the kernel structures (e.g., 3 different structures), including the initial kernel structure. In examples, the transmitter and receiver (e.g., a WTRU and a gNB) may have determined an intermediate code

$${R}_{1} = \frac{1}{2}$$

to use for the first retransmission. The WTRU may calculate the reliabilities of information bits associated with one or more (e.g., all) the codes designed from these structures as given in Table 2.

TABLE 2
Reliabilities of encoder inputs for different kernel structures

| Kernel | Reliability Score | | | | | | | | | | | |
|---|---|---|---|---|---|---|---|---|---|---|---|---|
| Structure | u₁ | u₂ | u₃ | u₄ | u₅ | u₆ | u₇ | u₈ | u₉ | u₁₀ | u₁₁ | u₁₂ |
| {T₂, T₂, T₃} | 0.0002 | 0.0662 | 0.1211 | 0.0837 | 0.5452 | 0.6836 | 0.1780 | 0.7009 | 0.8086 | 0.8240 | 0.9924 | 0.9961 |
| {T₂, T₃, T₂} | 0.0002 | 0.0310 | 0.0881 | 0.5056 | 0.1914 | 0.6836 | 0.1780 | 0.6658 | 0.7932 | 0.9880 | 0.8789 | 0.9961 |
| {T₃, T₂, T₂} | 0.0002 | 0.0310 | 0.0549 | 0.4138 | 0.1526 | 0.6287 | 0.7385 | 0.9802 | 0.3164 | 0.8086 | 0.8789 | 0.9961 |

The WTRU may select the kernel structure based on the reliabilities of the inputs. For example, the WTRU may select the 6 inputs and/or compute their average reliabilities for each kernel structure. In the example shown in table 2, the kernel structure selected may be {T₃, T₂, T₂} based on the reliabilities. For example, the kernel selection process may comprise computing the average reliabilities for the 6 best inputs. Hence, in the first retransmission, the WTRU may switch kernel structure from {T₂, T₃, T₂} to {T₃, T₂, T₂}.

Following the selection of the kernel structure, in examples, the transmitter may determine the mapping of the information bits to encoder inputs (e.g., bit channels). S_{b}={b₁:μ₁, b₂: μ₂, . . . , b₉:μ₉} may denote the undecoded information bit set, and μᵢ may denote the highest reliability related to bᵢ in previous transmissions. For example, the information bits with lowest reliability in S_{b} may be retransmitted and/or assigned to encoder inputs as given in Table 3. One or more (e.g., all) other encoder inputs may be frozen.

TABLE 3
Mapping Information Bits to Encoder Inputs
for 2^{nd} Transmission based on {T₃, T₂, T₂}.

| Information bits in | | | | | | |
|---|---|---|---|---|---|---|
| 2^{nd} transmission | b₁ | b₂ | b₃ | b₄ | b₅ | b₆ |
| Encoder Input | u₆ | u₇ | u₈ | u₉ | u₁₀ | u₁₁ |
| Reliability Order | 6 | 5 | 2 | 4 | 3 | 1 |
| (given in Table 2) | | | | | | |
| Reliability | 0.6287 | 0.7385 | 0.9802 | 0.8086 | 0.8789 | 0.9961 |
| (given in Table 2) | | | | | | |

If information bits in the first retransmission were successfully decoded, then the decoded information bits may be used as new frozen bits in the original transmission and/or S_{b} may be updated. If one or more (e.g., all) information bits in the original transmission are still not decodable, then, a second retransmission may be sent. In the second retransmission, the information bits may be selected from the undecoded information bits set S_{b} (e.g., b₇, b₈, b₉) of Table 1. In examples, the rest of the information bits may have been already decoded during the process of the first retransmission.

If the information bits of the first retransmission were not successfully decoded, in examples, for the second retransmission the information bits with lowest reliability in the updated set S_{b}, e.g., b₁, b₂, b₄, may be retransmitted at the rate

$${R}_{2} = \frac{1}{4} .$$

One or more (e.g., all) other encoder inputs may be frozen for the second retransmission. For example, the WTRU may receive second feedback from the receiver for the first retransmission. The second feedback may indicate that at least a second subset of the data bits were not successfully decoded by the receiver. The second subset of the data bits may be a subset of the first subset of the data bits. The WTRU may encode at least the second subset of the data bits using a polar code associated with a third polar code kernel structure. The third polar code kernel structure may include a third kernel order, a third kernel size, and/or a third kernel structure. The second subset of the data bits may be encoded using relatively higher reliability bit channels of the third polar code kernel structure than a reliability associated with one or more bit channels that were used for encoding the second subset of the data bits using the second polar code kernel structure of the first retransmission. The WTRU may send a second retransmission to the receiver that includes the polar coded second subset of the data bits

The receiver may provide feedback to the transmitter indicating the status of the decoding of one or more (e.g., all) received transmissions. The feedback may indicate the status of undecoded data bits after receiving the (re) transmission. The feedback may be sent with ACK/NACK messages that may indicate the decoding outcome of the (re) transmission. If a subsequent retransmission is indicated for (e.g., because a subset of data bits were not decoded successfully), the WTRU may apply similar (e.g., the same) procedures to compute the new kernel order and/or mapping of information bits to encoder inputs.

The procedure for enabling the IF-HARQ process for multi-kernel polar codes may be described herein. A WTRU (e.g., a transmitter) and a receiver (e.g., a network device such as a gNB or another WTRU) may align on the multi-kernel polar coding configurations. The WTRU may transmit with an initial (e.g., anchor) code rate R₀ and/or an agreed codeword length. The WTRU may transmit the initial code rate and/or agreed codeword length after the link adaption procedure. The receiver may receive the codeword and/or decode the codeword. The receiver may send an indication/feedback for ACK/NACK. If NACK is received by the WTRU, the transmitter may initiate the IF-HARQ process. If an ACK is received, the transmission may have been successful.

In examples, for a retransmission the transmitter may determine the new code rate and/or report the new code rate to the receiver. The transmitter may determine the code rate, for example, based on the link SNR. The code rate may be determined according to the following options: The code rate can be implicit and/or may not be reported when a static IF-HARQ is employed. The code rate may be determined based on a lookup table that matches SNR and code rate values, in the case of Dynamic IF-HARQ by choosing an adjustment parameter Δᵢ such that Rⱼ₊₁=Rⱼ×Δⱼ. The code rate may be data-driven based on a predictor that outputs the code rate with respect to the SNR, the codelength and/or the previous code rate, e.g., Rⱼ₊₁=f(Rⱼ, N, SNR).

In examples, the transmitter may send a message to receiver to indicate the code rate and/or confirmation of retransmission. The transmitter may start the process of determining and/or selecting the polar code kernel structure. The transmitter may generate the set of reordered kernel structures, and/or calculate the reliabilities of inputs of the polar encoder. The WTRU may select the polar code kernel structure based on the number of retransmitted information bits and/or corresponding reliabilities. The transmitter may determine the mapping of information bits to encoder inputs. In the first transmission, one or more (e.g., all) information bits may be mapped to encoder inputs with highest reliabilities. If there may be a retransmission, in the j-th retransmission, the transmitter may select RⱼN information bits based on the decoding success of the previous retransmissions and/or corresponding reliabilities of the information bits in the previous transmissions. The transmitter and/or receiver may align regarding the new kernel structure and/or mapping of information bits to encoder inputs. In examples, the kernel structure and/or mapping may be implicit to both transmitter and/or receiver given the SNR, code rate and/or codeword length. In examples, the transmitter may indicate the new kernel order and/or mapping to the receiver. A similar (e.g., the same) process may repeat iteratively until a successful decoding of one or more (e.g., all) information bits and/or reaching Nₘₐₓ (e.g., the maximum number of retransmissions).

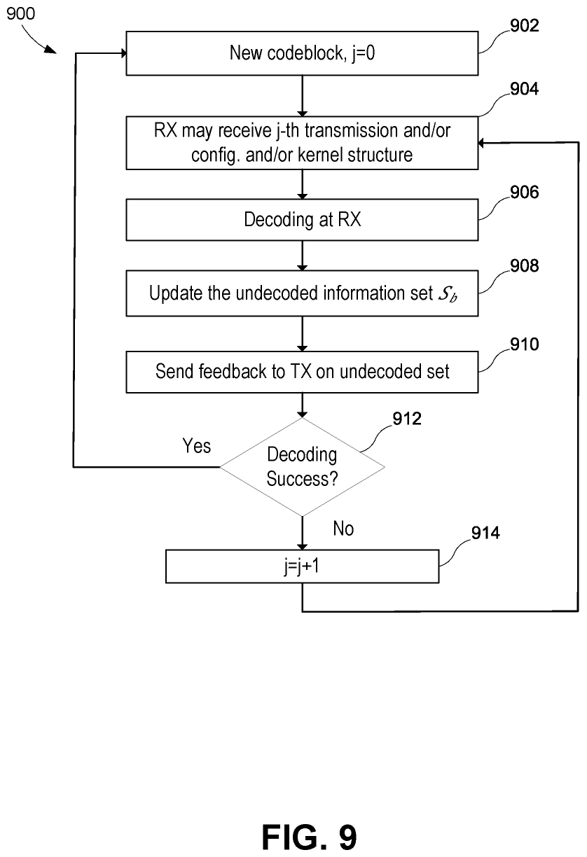

FIG. 9 is a flowchart depicting an example IF-HARQ process 900 performed by a receiver. At 902, there may be a new code block, which may be transmitted to the receiver. At 904, the receiver may receive an indication of a polar code kernel structure, an indication of a mapping of data bits to bit channels, and/or a transmission (e.g., an initial transmission, a first retransmission, a j-th retransmission). At 906, the receiver may decode the transmission (e.g., a transmitted codeword). At 908, the receiver may update the set of undecoded information. At 910, the receiver may send feedback to the transmitter. The feedback sent by the receiver at 910 may be based on the undecoded information set. The feedback sent by the receiver at 910 may indicate that a subset of the data bits were not successfully decoded. If a subset of the data bits were not successfully decoded by the receiver, the feedback sent by the receiver at 910 may be NACK message. At 912, the process differs based on whether the data bits were decoded successfully at 906. If the data bits were not decoded successfully, at 914 the receiver may update the number of transmissions received for the code block from j to j+1 and may prepare to receive a retransmission at 904. If the decoding was successful, the receiver may reset the process at 902.

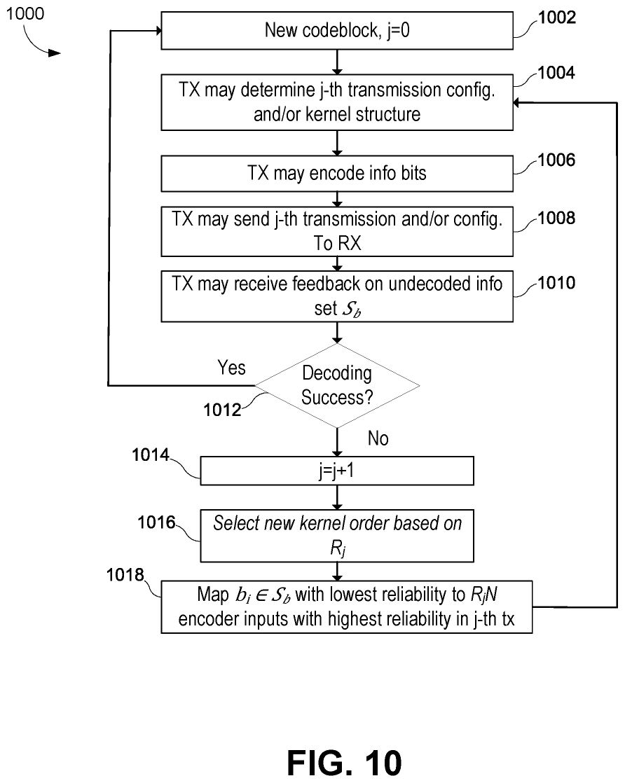

FIG. 10 is a flowchart depicting the example IF-HARQ process 1000 performed by a transmitter. At 1002, the transmitter may prepare to begin the IF-HARQ process for a new code block, with j=0 prior data bit transmissions. At 1004, the transmitter may determine and/or select a polar code kernel structure and/or mapping of data bits to bit channels of a polar code for a first transmission or j-th retransmission. At 1006, the transmitter may encode the data bits using the polar code kernel structure and mapping of data bits to bit channels of the polar code kernel structure. At 1008, the transmitter may transmit (e.g., the initial transmission, the j-th retransmission) the encoded data bits to a receiver. At 1010, the transmitter may receive feedback from the receiver. The feedback received at 1010 may indicate that a subset of data bits were not successfully decoded by the receiver, or that the decoding was successful. At 1012, if the decoding was successful, the transmitter may prepare to reset the IF-HARQ process for a new data block at 1002. If the feedback received at 1010 indicated that a subset of data bits were not successfully decoded by the receiver, at 1012 the transmitter may prepare to transmit a retransmission (e.g., a first retransmission, retransmission number j+1). At 1016, the transmitter may select a polar code kernel structure for the retransmission. The polar code kernel structure may be selected based on the code rate and/or the reliability of bit channels. At 1018, the transmitter may map the data bits to be transmitted to bit channels for a polar code kernel structure. In examples, the data bits that were not successfully decoded by the receiver may be mapped to bit channels with higher reliability for the next transmission.

For incremental freezing, there may be intermediate retransmission code rates. For each retransmission (e.g., following an unsuccessful decoding by the receiver), a new intermediate code rate may be defined. A decoding failure may mean that the actual channel conditions were worse than the estimated channel conditions. For the i-th retransmission, a new intermediate code rate Rᵢ may be defined.

For Static Incremental Freezing (SIF), intermediate code rates may be pre-determined for a given peak code rate R₀. In examples, a set of pre-defined code rates R={R₀, R₁, . . . , R_{N}_{ₘₐₓ}} may be signaled and/or pre-determined between the transmitter and receiver. For example, Nₘₐₓ may denote the maximum number of retransmissions. If Rⱼ can be determined based on R₀ (e.g., solely based on R₀), the method may be considered SIF. In examples of SIF, Rᵢ=f(R₀), j>0,0<Rⱼ<1.

An example code rate set may be computed based on

$${R}_{j} = \frac{{R}_{0}}{j + 1} , j > 0.$$

The intermediate code rates may be reduced by factor

$$\frac{1}{j + 1}$$

relative R₀ at each retransmission. A example code rate set may be computed based on

$${R}_{j} = \frac{{R}_{0}}{{2}^{j}} , j > 0.$$

An example code rate set may be such that

$$R = \{ {R}_{0} , \frac{{R}_{0}}{c} , {R}_{0} , \frac{{R}_{0}}{c} , … \} ,$$

where c>1 and one or more (e.g., all) information bits may be encoded periodically/semi-periodically in case previous retransmissions fail to recover any information bits. The periodicity of intermediate code rate R₀ may change depending on the success of the decoding of previous transmissions.

For Dynamic Incremental Freezing (DIF), the intermediate code rates may dynamically change between retransmissions. In examples, the intermediate code rates may change depending on the SNR and/or success of the decoding of previous transmissions. In examples, R={R₀, R₁, . . . , R_{N}_{ₘₐₓ}} may denote the set of code rates, and the intermediate code rates may be described as Rⱼ=ΔⱼR₀, where 0<Δⱼ≤1 may be a rate scaling parameter to dynamically adjust the intermediate code rates. The rate scaling parameter Δⱼ may be signaled for each retransmission from transmitter to receiver.

For Machine Learning based Incremental Freezing (ML-IF), the intermediate code rates may be determined by a ML/predictor block. The inputs to the ML block may be the predicted SNR values for each transmission and/or previous code rates. The output of the ML block may provide either directly or indirectly the next intermediate code rate. Example ML blocks may include neural network and/or reinforcement learning techniques.

Decoding of polar codes with an incremental freezing scheme for multi-kernel structure polar codes may be based on a decoding scheme such as chase combining, sequential decoding, parallel decoding, etc. In a chase combining scheme, the same information and/or frozen bits may be retransmitted for a set of retransmissions. The decoder may combine the received symbols to increase the received SNR and/or decode the combined codeword. In a sequential decoding scheme, the decoding may start from the latest received codeword that is followed by the decoding of previous codewords sequentially. If a retransmitted codeword can be successfully decoded, for example, the recovered information bits may be set as frozen bits for the decoding of previously received codewords. In a parallel decoding scheme, one or more (e.g., all) received codewords may be decoded in parallel each time a new retransmitted codeword is received. The log likelihood ratio (LLR) values used in the decoding process of one or more (e.g., all) retransmitted codewords may be jointly updated during the parallel decoding scheme.

Signaling may occur between a transmitter and a receiver, for example, to enable the multi-kernel structure selection. In examples, the transmitter may be a WTRU or a network device. In examples, the receiver may be a WTRU or network device. In examples, the transmitter and/or receiver may be aligned on the intermediate code rates and/or the polar code kernel structure. In examples, the intermediate code rate may be explicitly shared with a signaling message between the transmitter and the receiver. In examples, the polar code kernel structure may be signaled between the transmitter and the receiver. In examples, the intermediate code rate and/or kernel structure may be implicit. For example, the transmitter and the receiver may be aligned on a pre-determined code rate.

In case of a decoding failure, for example, the receiver may inform the transmitter of the decoding status of one or more (e.g., all) the transmissions received so far. At each retransmission, some of the information bits may be decoded (e.g., but not all). In examples, information on the undecoded set may be sent from the receiver to the transmitter by enabling ACK/NACK messages for one or more (e.g., all) retransmissions received for a data block. For example, the receiver may signal an ACK/NACK message after the decoding process of each retransmission. In examples, the receiver may send a 1 bit ACK/NACK after original transmission, a 2 bit ACK/NACK after the first retransmission, a 3 bit ACK/NACK after second retransmission, and so on. For example, an ACK/NACK feedback of 011 after the second retransmission may inform the transmitter that decoding of the original transmission was unsuccessful, but the decoding of the information bits in first and/or second retransmissions was successful. Based on the ACK/NACK feedback, the transmitter and/or receiver may update the undecoded information set accordingly.

In examples, signaling between a WTRU and a gNB may use control and/or data channels, dynamically and/or semi-statically, such as UCI over PUCCH/PUSCH, DCI over PDCCH, and/or MAC CE. The implicit signaling between the WTRU and gNB may include selection of certain UL resources for control and/or data, such as using a specific PUCCH resource, RACH resources, SRS resource, spatialrelationInfo, etc.

Transmissions and retransmissions may be performed to enable IF-HARQ for multi-kernel polar codes. In case of decoding failure, a WTRU may indicate that a subset of the data bits were not successfully decoded (e.g., via a NACK message to the network (e.g., gNB)). The WTRU may receive a retransmission which is encoded as described herein. Encoding the retransmission may include updating an undecoded set of information bits and/or corresponding reliabilities using the feedback provided by the WTRU. Encoding the retransmission may include determining one or more (e.g., all) kernel structures with different ordering of the kernel structure in the original first transmission. Encoding the retransmission may include computing the reliability score of each encoder input for one or more (e.g., all) kernel structures. Encoding the retransmission may include computing a metric for each kernel structure, for example, average of the reliabilities of the encoder inputs with highest reliabilities for a given number of encoder inputs determined using the intermediate code rates. Encoding the retransmission may include selecting the best kernel structure based on the metric used for the kernel performance function. Encoding the retransmission may include selecting the information bits with lowest reliabilities in the undecoded set. Encoding the retransmission may include mapping information bits to encoder inputs that have the highest reliabilities. Encoding the retransmission may include encoding the information bits and/or generating a codeword. The WTRU may decode the retransmitted code block. The WTRU may indicate feedback (e.g., a ACK/NACK message) for each of the retransmitted code block to inform the network about the set of decoded information bits.

Although features and elements are described above in particular combinations, one of ordinary skill in the art will appreciate that each feature or element can be used alone or in any combination with the other features and elements. In addition, the methods described herein may be implemented in a computer program, software, or firmware incorporated in a computer-readable medium for execution by a computer or processor. Examples of computer-readable media include electronic signals (transmitted over wired or wireless connections) and computer-readable storage media. Examples of computer-readable storage media include, but are not limited to, a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs). A processor in association with software may be used to implement a radio frequency transceiver for use in a WTRU, UE, terminal, base station, RNC, or any host computer.

What is claimed is:

1-20. (canceled)

21. A method implemented by an encoding device, the method comprising:
encoding data bits using a polar code associated with a first polar code kernel structure;
sending an initial transmission to a receiver, the initial transmission comprising the polar coded data bits;
receiving first feedback from the receiver for the initial transmission, wherein the first feedback indicates that at least a first subset of the polar coded data bits were not successfully decoded by the receiver;
encoding at least the first subset of the polar coded data bits that were not successfully decoded by the receiver using a polar code associated with a second polar code kernel structure, wherein the first subset of the polar coded data bits are encoded using relatively higher reliability bit channels of the second polar code kernel structure than a reliability associated with one or more bit channels that were used for encoding the first subset of the polar coded data bits using the first polar code kernel structure of the initial transmission; and
sending a first retransmission to the receiver, the first retransmission comprising the polar coded first subset of the polar coded data bits associated with the second polar code kernel structure.

22. The method of claim 21, further comprising:
receiving second feedback from the receiver for the first retransmission, wherein the second feedback indicates that at least a second subset of the polar coded data bits were not successfully decoded by the receiver, the second subset of the polar coded data bits being a subset of the first subset of the polar coded data bits;
encoding at least the second subset of the polar coded data bits using a polar code associated with a third polar code kernel structure, wherein the second subset of the polar coded data bits are encoded using relatively higher reliability bit channels of the third polar code kernel structure than a reliability associated with one or more bit channels that were used for encoding the second subset of the polar coded data bits using the second polar code kernel structure of the first retransmission; and
sending a second retransmission to the receiver, the second retransmission comprising the polar coded second subset of the polar coded data bits.

23. The method of claim 21, further comprising:
sending one or more of an indication of the first polar code kernel structure or second polar code kernel structure for the first retransmission or an indication of a mapping of the first subset of the polar coded data bits to the bit channels of the second polar code kernel structure to the receiver.

24. The method of claim 21, wherein the first feedback indicating that at least the first subset of the polar coded data bits were not successfully decoded by the receiver comprises one or more NACK messages.

25. The method of claim 21, further comprising:
determining a code rate for the initial transmission based on a modulation and coding scheme (MCS).

26. The method of claim 21, wherein the polar coded data bits are mapped to the one or more bit channels in the initial transmission and the first retransmission based on respective reliabilities of the polar coded data bits.

27. The method of claim 21, wherein the first polar code kernel structure comprises a first kernel order, a first kernel size, or a first kernel structure, and wherein the second polar code kernel structure comprises a second kernel order, a second kernel size, or a second kernel structure.

28. The method of claim 21, further comprising:
selecting the first polar code kernel structure based on channel quality, a size of resources, encoder complexity, or reliability; and
selecting the second polar code kernel structure based on a code rate, wherein the code rate is associated with the first transmission.

29. The method of claim 21, further comprising:
determining a code rate for the first retransmission based on a pre-defined set of code rates.

30. The method of claim 21, further comprising:
determining a code rate for the first retransmission based on a signal to noise ratio associated with the initial transmission.

31. An encoding device comprising:
a processor, the processor configured to:
encode data bits using a polar code associated with a first polar code kernel structure;
send an initial transmission to a receiver, the initial transmission comprising the polar coded data bits;
receive first feedback from the receiver for the initial transmission, wherein the first feedback indicates that at least a first subset of the polar coded data bits were not successfully decoded by the receiver;
encode at least the first subset of the polar coded data bits that were not successfully decoded by the receiver using a polar code associated with a second polar code kernel structure, wherein the first subset of the polar coded data bits are encoded using relatively higher reliability bit channels of the second polar code kernel structure than a reliability associated with a one or more bit channels that were used for encoding the first subset of the polar coded data bits using the first polar code kernel structure of the initial transmission; and
send a first retransmission to the receiver, the first retransmission comprising the polar coded first subset of the polar coded data bits associated with the second polar code kernel structure.

32. The encoding device of claim 31, wherein the processor is further configured to:
receive second feedback from the receiver for the first retransmission, wherein the second feedback indicates that at least a second subset of the polar coded data bits were not successfully decoded by the receiver, the second subset of the polar coded data bits being a subset of the first subset of the polar coded data bits;
encode at least the second subset of the polar coded data bits using a polar code associated with a third polar code kernel structure, wherein the second subset of the polar coded data bits are encoded using relatively higher reliability bit channels of the third polar code kernel structure than a reliability associated with one or more bit channels that were used for encoding the second subset of the polar coded data bits using the second polar code kernel structure of the first retransmission; and
send a second retransmission to the receiver, the second retransmission comprising the polar coded second subset of the polar coded data bits.

33. The encoding device of claim 31, wherein the processor is further configured to:
send one or more of an indication of the first polar code kernel structure or second polar code kernel structure for the first retransmission or an indication of a mapping of the first subset of the polar coded data bits to the bit channels of the second polar code kernel structure to the receiver.

34. The encoding device of claim 31, wherein the first feedback indicating that at least the first subset of the polar coded data bits were not successfully decoded by the receiver comprises one or more NACK messages.

35. The encoding device of claim 31, wherein the processor is further configured to:
determine a code rate for the initial transmission based on a modulation and coding scheme (MCS).

36. The encoding device of claim 31, wherein the polar coded data bits are mapped to the one or more bit channels in the initial transmission based on respective reliabilities of the polar coded data bits.

37. The encoding device of claim 31, wherein the first polar code kernel structure comprises a first kernel order, a first kernel size, or a first kernel structure, and wherein the second polar code kernel structure comprises a second kernel order, a second kernel size, or a second kernel structure.

38. The encoding device of claim 31, wherein the processor is further configured to:
select the first polar code kernel structure based on channel quality, a size of resources, encoder complexity, or reliability; and
select the second polar code kernel structure based on a code rate, wherein the code rate is associated with the first transmission.

39. The encoding device of claim 31, wherein the processor is further configured to:
determine a code rate for the first retransmission based on a pre-defined set of code rates.

40. The encoding device of claim 31, wherein the processor is further configured to:
determine a code rate for the first retransmission based on a signal to noise ratio associated with the initial retransmission.
